(19) United States
(12) Patent Application Publication
(10) Pub. No.: US 2015/0061010 A1
(43) Pub. Date: Mar. 5, 2015

(54) STRUCTURE FOR IMPROVED CONTACT RESISTANCE AND EXTENSION DIFFUSION CONTROL

(71) Applicant: International Business Machines Corporation, Armonk, NY (US)

(72) Inventors: Kangguo Cheng, Schenectady, NY (US); Bruce B. Doris, Slingerlands, NY (US); Ali Khakifirooz, Mountain View, CA (US); Alexander Reznicek, Troy, NY (US)

(73) Assignee: International Business Machines Corporation, Armonk, NY (US)

(21) Appl. No.: 14/011,235

(22) Filed: Aug. 27, 2013

(51) Int. Cl. H01L 29/78; H01L 29/06; H01L 21/265; H01L 29/66

(52) U.S. Cl. CPC H01L 29/7833; H01L 29/66409; H01L 29/0692; H01L 21/265
USPC 257/344; 438/300

(57) ABSTRACT

Semiconductor structures are provided including a raised source region comprising, from bottom to top, a source-side phosphorus doped epitaxial semiconductor material portion and a source-side arsenic doped epitaxial semiconductor material portion and located on one side of a gate structure, and a raised drain region comprising from bottom to top, a drain-side phosphorus doped epitaxial semiconductor material portion and a drain-side arsenic doped epitaxial semiconductor material portion and located on another side of the gate structure.

### BACKGROUND

The present application relates to semiconductor structures and methods of forming the same. More particularly, the present application relates to semiconductor structures containing a raised source region and a raised drain region each including a material stack, from bottom to top, of a phosphorus doped epitaxial semiconductor material portion and an arsenic doped epitaxial semiconductor material portion, and methods of forming such semiconductor structures.

Field effect transistors (FETs) have inherent device resistance, including parasitic resistances, which may be modeled as a resistor in series with the switch. Performance depends upon how fast the circuit can charge and discharge the capacitive load, i.e., the circuit's switching speed. Device resistances limit current supplied by a particular device and slow capacitive switching. Thus, how fast the circuit switches the particular load depends both upon device on-current (e.g., which is selected by design) and the device resistances. Thus, circuit performance is maximized by maximizing device on-current and minimizing unwanted device resistance.

Another design concern is that, as FET features have shrunk, what are collectively known as short channel effects have become more pronounced, resulting in a rapid increase of static power consumption. Short channel effects have occurred, in part, from a threshold voltage reduction as the FET gate length is reduced. Such threshold voltage dependence on gate length, also known as threshold voltage roll-off, has been mitigated by thinning the transistor gate dielectric material. Unfortunately, especially as FET features have shrunk, thinner gate dielectric materials have resulted in increased gate leakages or gate induced leakages (e.g., gate to channel, gate to source or drain and gate induced drain leakage (GIDL)). Therefore, for circuits with transistor gate lengths shorter than 100 nm, the circuit stand-by power has become comparable to the active power.

Short channel effects are known to improve inversely with channel thickness. For silicon on insulator (SOI) semiconductor devices, sub-threshold leakage and other short channel effects have been controlled and reduced by thinning the surface silicon layer, i.e., the device channel layer. Fully depleted (FD) devices (e.g., FDSOI devices) or partially depleted (PD) devices (e.g., PDSOI devices) have been formed in ultrathin SOI and/or extremely-thin SOI (ETSOI), for example, where the silicon channel layer is less than 50 nm or, in some cases, less than 20 nm. Ultrathin FDSOI devices operate at lower effective voltage fields. Additionally, these ultrathin SOI layers can be doped for higher mobility, which in turn increases device current and improves circuit performance. Furthermore, ultrathin FDSOI devices have a steeper sub-threshold current swing with current falling off sharply as the gate to source voltage drops below the threshold voltage.

Unfortunately, however, forming source/drain (S/D) regions that are made from the same ultrathin silicon layer increases external resistance and, in particular, contacts resistance. Similar high resistance S/D diffusion and contact problems have been encountered in bulk silicon complementary metal oxide semiconductor (CMOS) devices with lightly doped drain (LDD) devices, where the S/D regions are maintained very shallow for lower voltage operation. Silicide has been tried to reduce this external resistance but has not been problem free. Especially for these very short devices, unless the S/D silicide is spaced away from the gate, the silicide can cause gate to channel or S/D shorts, for example. In addition, silicide can interfere or interact with high-k gate dielectric formation and vice versa.

### SUMMARY

Semiconductor structures (planar and non-planar) are provided including a raised source region comprising, from bottom to top, a source-side phosphorus doped epitaxial semiconductor material portion and a source-side arsenic doped epitaxial semiconductor material, and a raised drain region comprising from bottom to top, a drain-side phosphorus doped epitaxial semiconductor material portion and a drain-side arsenic doped epitaxial semiconductor material portion.

In one aspect of the present application, a semiconductor structure is provided. The semiconductor structure of the present application includes a gate structure located on a first portion of a semiconductor material. The semiconductor structure of the present application further includes a raised source region located on a second portion of the semiconductor material and on one side of the gate structure. The raised source region of the semiconductor structure of the present application includes, from bottom to top, a source-side phosphorus doped epitaxial semiconductor material portion and a source-side arsenic doped epitaxial semiconductor material portion. The semiconductor structure of the present application also includes a raised drain region located on a third portion of the semiconductor material and on another side of the gate structure. The raised drain region of the semiconductor structure of the present application includes from bottom to top, a drain-side phosphorus doped epitaxial semiconductor material portion and a drain-side arsenic doped epitaxial semiconductor material portion.

In another aspect of the present application, a method of forming a semiconductor structure is provided. The method of the present application includes forming a gate structure on a first portion of a semiconductor material. Next, a source-side phosphorus doped epitaxial semiconductor material portion is formed on one side of the gate structure, and a drain-side phosphorus doped epitaxial semiconductor material portion is also formed on another side of the gate structure. A source-side arsenic doped epitaxial semiconductor material portion is then formed on an uppermost surface of said source-side phosphorus doped epitaxial semiconductor material portion, and a drain-side arsenic doped epitaxial semiconductor material portion is also formed on an uppermost surface of the drain-side phosphorus doped epitaxial semiconductor material portion. Dopant, i.e., phosphorus, from the source-side phosphorus doped epitaxial semiconductor material portion is then diffused downwards into a second portion of the semiconductor material and formation of a source region, and dopant, i.e., phosphorus, from the drain-side phosphorus doped epitaxial semiconductor material portion is then diffused downwards into the a third portion of the semiconductor material and formation of a drain region.

### BRIEF DESCRIPTION OF THE DRAWINGS

FIG. 1 is a cross-sectional view illustrating an initial semiconductor structure including a gate structure located on a first portion of a semiconductor material and a first dielectric spacer on each vertical sidewall surface of the gate structure that can be employed in one embodiment of the present application.

FIG. 2 is a cross sectional view of the structure shown in FIG. 1 after forming a source-side phosphorus doped epitaxial semiconductor material portion on one side of the gate structure, and a drain-side phosphorus doped epitaxial semiconductor material portion on another side of the gate structure.

FIG. 3 is a cross sectional view of the structure shown in FIG. 2 after forming a source-side arsenic doped epitaxial semiconductor material portion on an uppermost surface of the source-side phosphorus doped epitaxial semiconductor material portion and on one side of the gate structure, and a drain-side arsenic doped epitaxial semiconductor material portion on an uppermost surface of the drain-side phosphorus doped epitaxial semiconductor material portion and on another side of the gate structure and annealing.

FIG. 4 is a cross sectional view of the structure shown in FIG. 3 after forming a second dielectric spacer.

FIG. 5 is a cross sectional view of the structure shown in FIG. 4 after forming a source-side metal semiconductor alloy on a surface of the source-side arsenic doped epitaxial semiconductor material portion and a drain-side metal semiconductor alloy on a surface of the drain-side arsenic doped epitaxial semiconductor material portion.

FIG. 6A is a top-down view of a semiconductor structure containing a plurality of semiconductor fins located on a insulator layer of an SOI substrate in accordance with an embodiment of the present application.

FIG. 6B is a vertical cross-sectional view of the semiconductor structure along the vertical plane B-B′ of FIG. 6A.

FIG. 6C is a vertical cross-sectional view of the semiconductor structure along the vertical plane C-C′ of FIG. 6A.

FIG. 6D is a vertical cross-sectional view of the semiconductor structure along the vertical plane D-D′ of FIG. 6A.

FIG. 7A is a top-down view of the semiconductor structure 6A after formation of a gate structure that is orientated perpendicular to and that straddles each semiconductor fin.

FIG. 7B is a vertical cross-sectional view of the semiconductor structure along the vertical plane B-B′ of FIG. 7A.

FIG. 7C is a vertical cross-sectional view of the semiconductor structure along the vertical plane C-C′ of FIG. 7A.

FIG. 7D is a vertical cross-sectional view of the semiconductor structure along the vertical plane D-D′ of FIG. 7A.

FIG. 8A is a top-down view of the semiconductor structure shown in FIG. 7A after forming a gate spacer.

FIG. 8B is a vertical cross-sectional view of the semiconductor structure along the vertical plane B-B′ of FIG. 8A.

FIG. 8C is a vertical cross-sectional view of the semiconductor structure along the vertical plane C-C′ of FIG. 8A.

FIG. 8D is a vertical cross-sectional view of the semiconductor structure along the vertical plane D-D′ of FIG. 8A.

FIG. 9A is a top-down view of the semiconductor structures shown in FIG. 8A after forming a source-side phosphorus doped epitaxial semiconductor material portion on one side of the gate structure and a drain-side phosphorus doped epitaxial semiconductor material portion on another side of the gate structure.

FIG. 9B is a vertical cross-sectional view of the semiconductor structure along the vertical plane B-B′ of FIG. 9A.

FIG. 9C is a vertical cross-sectional view of the semiconductor structure along the vertical plane C-C′ of FIG. 9A.

FIG. 9D is a vertical cross-sectional view of the semiconductor structure along the vertical plane D-D′ of FIG. 9A.

FIG. 10A is a top-down view of the semiconductor structures shown in FIG. 9A after forming a source-side arsenic doped epitaxial semiconductor material portion on one side of the gate structure and on the source-side phosphorus doped epitaxial semiconductor material portion and a drain-side arsenic doped epitaxial semiconductor material portion on another side of the gate structure and on the drain-side phosphorus doped epitaxial semiconductor material portion and annealing.

FIG. 10B is a vertical cross-sectional view of the semiconductor structure along the vertical plane B-B′ of FIG. 10A.

FIG. 10C is a vertical cross-sectional view of the semiconductor structure along the vertical plane C-C′ of FIG. 10A.

FIG.10D is a vertical cross-sectional view of the semiconductor structure along the vertical plane D-D′ of FIG. 10A.

FIG. 11A is a top-down view of the semiconductor structures shown in FIG. 10A after forming a source-side metal semiconductor alloy on one side of the gate structure and on the source-side arsenic doped epitaxial semiconductor material portion and a drain-side metal semiconductor alloy on another side of the gate structure and on the drain-side arsenic doped epitaxial semiconductor material portion.

FIG. 11B is a vertical cross-sectional view of the semiconductor structure along the vertical plane B-B′ of FIG. 11A.

FIG. 11C is a vertical cross-sectional view of the semiconductor structure along the vertical plane C-C′ of FIG. 11A.

FIG. 11D is a vertical cross-sectional view of the semiconductor structure along the vertical plane D-D′ of FIG. 11A.

FIG. 12A is a top-down view the structure shown in FIG. 8A after forming a faceted raised source region and a faceted raised drain region and annealing in accordance with an embodiment of the present application.

FIG. 12B is a vertical cross-sectional view of the semiconductor structure along the vertical plane B-B′ of FIG. 12A.

FIG. 12C is a vertical cross-sectional view of the semiconductor structure along the vertical plane C-C′ of FIG. 12A.

FIG. 12D is a vertical cross-sectional view of the semiconductor structure along the vertical plane D-D′ of FIG. 12A.

FIG. 13A is a top-down view the structure shown in FIG. 12A after forming a faceted source-side metal semiconductor alloy atop the faceted raised source region and a faceted drain-side metal semiconductor alloy atop the faceted raised drain region.

FIG. 13B is a vertical cross-sectional view of the semiconductor structure along the vertical plane B-B′ of FIG. 13A.

FIG. 13C is a vertical cross-sectional view of the semiconductor structure along the vertical plane C-C′ of FIG. 13A.

FIG. 13D is a vertical cross-sectional view of the semiconductor structure along the vertical plane D-D′ of FIG. 13A.

### DETAILED DESCRIPTION

The present application, which provides semiconductor structures containing a raised source region and a raised drain region each including a material stack, from bottom to top, of a phosphorus doped epitaxial semiconductor material portion and an arsenic doped epitaxial semiconductor material portion, and methods of forming such semiconductor structures, will now be described in greater detail by referring to the following discussion and drawings that accompany the present application. It is noted that the drawings of the present application are provided for illustrative purposes and, as such, they are not drawn to scale. In the drawings and the description that follows, like elements are referred to by like reference numerals.

In the following description, numerous specific details are set forth, such as particular structures, components, materials, dimensions, processing steps and techniques, in order to provide a thorough understanding of the present application. However, it will be appreciated by one of ordinary skill in the art that the present application may be practiced with viable alternative process options without these specific details. In other instances, well-known structures or processing steps have not been described in detail in order to avoid obscuring the various embodiments of the present application.

In some applications, phosphorus doped raised source/drain epitaxy is used to form phosphorus doped raised source/drain regions which may be used to merge neighboring semiconductor fins that are located on a surface of a substrate. Phosphorus doped raised source/drain regions can be readily employed for formation of doped extension regions utilizing a drive-in anneal process, but they have a high contact resistance which is particularly pertinent at ever shrinking dimensions. Arsenic doped raised source/drain regions have very low contact resistance, but arsenic is difficult to form doped extension region by utilizing a drive-in anneal process.

In some embodiments of the present application, a semiconductor structure having improved contact resistance and extension diffusion control can be provided. In the present disclosure, phosphorus and arsenic doped epitaxial semiconductor layers are employed. First, a phosphorus doped epitaxial semiconductor material is provided on portions of a semiconductor material that lay on both sides of a gate structure, and thereafter an arsenic doped epitaxial semiconductor material is formed atop the phosphorus doped epitaxial semiconductor material and on both sides of the gate structure. The assumption that arsenic will cause excessive phosphorus diffusion does not apply in the present application, since the arsenic doped epitaxial semiconductor material is not formed by utilizing an ion implantation process. Therefore, and in some embodiments, no point defects are formed which would enhance phosphorus diffusion.

Reference is now made to FIGS. 1-5 which illustrate an embodiment of the present application in which a planar metal oxide semiconductor field transistor containing a raised source region and a raised drain region each including a material stack, from bottom to top, of a phosphorus doped epitaxial semiconductor material portion and an arsenic doped epitaxial semiconductor material portion is formed.

Reference is first made to FIG. 1 which illustrates an initial semiconductor structure including a gate structure 16 located on a first portion of a semiconductor material 14 and a first dielectric spacer 24 located on each vertical sidewall of the gate structure 16 that can be employed in one embodiment of the present application.

Although a single gate structure 16 is shown and described herein, a plurality of gate structures can be formed. In one embodiment of the present application and when a plurality of gate structures is present, each gate structure of the plurality of gate structures can be of the same conductivity type (i.e., n-type FETs or p-type FETs). In another embodiment of the present application and when a plurality of gate structures is present, a first set of gate structures of the plurality of gate structures can be a first conductivity type (i.e., n-type FETs or p-type FETs), and a second set of gate structures of the plurality of gate structures can be a second conductivity type which is opposite from the first conductivity type. In such instances, block mask technology can be used to form gate structures of a different conductivity type. Also, block mask technology can be used to form gate structures in which the gate dielectric material portion, and/or the gate conductor material portion can be composed of a different material.

In one embodiment of the present application and as illustrated in FIG. 1, the semiconductor material 14 is a topmost semiconductor layer (i.e., a semiconductor-on-insulator (SOI) layer) of a semiconductor-on-insulator substrate. In such an embodiment, the semiconductor material 14 is present on an uppermost surface of an insulator layer 12. The insulator layer 12 is present on an uppermost surface of a handle substrate 10. The handle substrate 10 provides mechanical support to the insulator layer 12 and the semiconductor material 14.

In some embodiments of the present application, the handle substrate 10 and the semiconductor material 14 of the SOI substrate may comprise the same, or different, semiconductor material. The term “semiconductor” as used herein in connection with the semiconductor material of the handle substrate 10 and the semiconductor material 14 denotes any semiconducting material including, for example, Si, Ge, SiGe, SiC, SiGeC, InAs, GaAs, InP or other like III/V compound semiconductors. Multilayers of these semiconductor materials can also be used as the semiconductor material of the handle substrate 10 and the semiconductor material 14. In one embodiment, the handle substrate 10 and the semiconductor material 14 are both comprised of silicon. In some embodiments, the handle substrate 10 is a non-semiconductor material including, for example, a dielectric material and/or a conductive material.

The handle substrate 10 and the semiconductor material 14 may have the same or different crystal orientation. For example, the crystal orientation of the handle substrate 10 and/or the semiconductor material 14 may be {100}, {110}, or {111}. Other crystallographic orientations besides those specifically mentioned can also be used in the present application. The handle substrate 10 and/or the semiconductor material 14 of the SOI substrate may be a single crystalline semiconductor material, a polycrystalline material, or an amorphous material. Typically, at least the semiconductor material 14 is a single crystalline semiconductor material. In some embodiments, the semiconductor material 14 that is located atop the insulator layer 12 can be processed to include semiconductor regions having different crystal orientations.

The insulator layer 12 of the SOI substrate may be a crystalline or non-crystalline oxide or nitride. In one embodiment, the insulator layer 12 is an oxide such as, for example, silicon dioxide. The insulator layer 12 may be continuous or it may be discontinuous. When a discontinuous insulator region is present, the insulator region exists as an isolated island that is surrounded by semiconductor material.

The SOI substrate may be formed utilizing standard processes including for example, SIMOX (separation by ion implantation of oxygen) or layer transfer. When a layer transfer process is employed, an optional thinning step may follow the bonding of two semiconductor wafers together. The optional thinning step reduces the thickness of the semiconductor layer to a layer having a thickness that is more desirable.

The thickness of semiconductor material 14 of the SOI substrate is typically from 10 nm to 100 nm, with a thickness from 50 nm to 70 nm being more typical. In some embodiments, and when an ETSOI (extremely thin semiconductor-on-insulator) substrate is employed, semiconductor material 14 of the SOI can have a thickness of less than 10 nm. If the thickness of the semiconductor material 14 is not within one of the above mentioned ranges, a thinning step such as, for example, planarization or etching can be used to reduce the thickness of semiconductor material 14 to a value within one of the ranges mentioned above. The insulator layer 12 of the SOI substrate typically has a thickness from 1 nm to 200 nm, with a thickness from 100 nm to 150 nm being more typical. The thickness of the handle substrate 10 of the SOI substrate is inconsequential to the present application.

In some embodiments (not shown), the semiconductor material 14 is a bulk semiconductor substrate in which the entirety of the substrate is composed of at least one semiconductor material.

In some other embodiments, hybrid semiconductor substrates which have different surface regions of different crystallographic orientations can be employed as semiconductor material 14. When a hybrid substrate is employed, an nFET is typically formed on a (100) crystal surface, while a pFET is typically formed on a (110) crystal plane. The hybrid substrate can be formed by techniques that are well known in the art. See, for example, U.S. Pat. No. 7,329,923, U.S. Publication No. 2005/0116290, dated Jun. 2, 2005 and U.S. Pat. No. 7,023,055, the entire contents of each are incorporated herein by reference.

The semiconductor material 14 may be doped, undoped or contain doped and undoped regions therein. For clarity, the doped regions are not specifically shown in the drawings of the present application. Each doped region within the semiconductor material 14 may have the same, or they may have different conductivities and/or doping concentrations. The doped regions that are present in the semiconductor material 14 can be formed by ion implantation process or gas phase doping.

In some embodiments (not shown in FIG. 1), the semiconductor material 14 can be processed to include at least one isolation region therein. The at least one isolation region can be a trench isolation region or a field oxide isolation region. The trench isolation region can be formed utilizing a conventional trench isolation process well known to those skilled in the art. For example, lithography, etching and filling of the trench with a trench dielectric such as an oxide may be used in forming the trench isolation region. Optionally, a liner may be formed in the trench prior to trench fill, a densification step may be performed after the trench fill and a planarization process may follow the trench fill as well. The field oxide isolation region may be formed utilizing a so-called local oxidation of silicon process. Note that the at least one isolation region provides isolation between neighboring gate structure regions, typically required when the neighboring gates have opposite conductivities, i.e., nFETs and pFETs. As such, the at least one isolation region separates an nFET device region from a pFET device region.

As mentioned above, a gate structure 16 is located on a first portion of the semiconductor material 14. The first portion of the semiconductor material 16 that is directly beneath the gate structure 16 can be referred to herein as a channel region of the MOSFET. The gate structure 16 shown in FIG. 1 includes a material stack of, from bottom to top, a gate dielectric material portion 18, a gate conductor material portion 20 and a dielectric cap 22. In some embodiments of the present application, the dielectric cap 22 can be omitted.

The gate structure 16 shown in FIG. 1 can be formed by a gate first process or a gate last process. In a gate first process a functional gate structure is formed on the first portion of semiconductor material 14. The term “functional gate structure” is used throughout the present application as a permanent gate structure (including at least material portions 18 and 20) used to control output current (i.e., flow of carriers in the channel) of a semiconducting device through electrical or magnetic fields.

Notably, and in a gate first process, a layer of a gate dielectric material is first formed on an uppermost surface of semiconductor material 14, a layer of gate conductor material is then formed on the layer of gate dielectric material, and an optional layer of dielectric cap material is then formed on the layer of gate conductor material.

The gate dielectric material that provides the gate dielectric material portion 18 of the functional gate structure can be an oxide, nitride, and/or oxynitride. In one example, the gate dielectric material that provides the gate dielectric material portion 18 of the functional gate structure can be a high k material having a dielectric constant greater than silicon dioxide. Exemplary high k dielectrics include, but are not limited to, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3 and each value of y is independently from 0 to 2. In some embodiments, a multilayered gate dielectric structure comprising different gate dielectric materials, e.g., silicon dioxide, and a high k gate dielectric can be formed.

The gate dielectric material used in providing the gate dielectric material portion 18 of the functional gate structure can be formed by any deposition technique including, for example, chemical vapor deposition (CVD), plasma enhanced chemical vapor deposition (PECVD), physical vapor deposition (PVD), sputtering, or atomic layer deposition. In one embodiment of the present application, the gate dielectric material used in providing the gate dielectric material portion 18 of the functional gate structure can have a thickness in a range from 1 nm to 10 nm. Other thicknesses that are lesser than or greater than the aforementioned thickness range can also be employed for the gate dielectric material.

The gate conductor material used in providing the gate conductor material portion 20 of the functional gate structure can include any conductive material including, for example, doped polysilicon, an elemental metal (e.g., tungsten, titanium, tantalum, aluminum, nickel, ruthenium, palladium and platinum), an alloy of at least two elemental metals, an elemental metal nitride (e.g., tungsten nitride, aluminum nitride, and titanium nitride), an elemental metal silicide (e.g., tungsten silicide, nickel silicide, and titanium silicide) or multilayered combinations thereof. The gate conductor material used in providing the gate conductor material portion 20 of the functional gate structure can be formed utilizing a deposition process including, for example, chemical vapor deposition (CVD), plasma enhanced chemical vapor deposition (PECVD), physical vapor deposition (PVD), sputtering, atomic layer deposition (ALD) or other like deposition processes. When a metal silicide is formed, a conventional silicidation process is employed. In one embodiment, the gate conductor material used in providing the gate conductor material portion 20 of the functional gate structure has a thickness from 1 nm to 100 nm. Other thicknesses that are lesser than or greater than the aforementioned thickness range can also be employed for the gate conductor material.

The dielectric cap material used in providing the dielectric cap 22 of the functional gate structure can be comprised of a dielectric oxide, nitride and/or oxynitride. In one example, silicon dioxide and/or silicon nitride can be used as the dielectric cap material. The dielectric cap material used in providing the dielectric cap 22 of the functional gate structure can be formed by a deposition process including, for example, chemical vapor deposition (CVD), plasma enhanced chemical vapor deposition (PECVD), physical vapor deposition (PVD), sputtering, or atomic layer deposition. In one embodiment of the present application, the dielectric cap material used in providing the dielectric cap 22 of the functional gate structure can have a thickness in a range from 25 nm to 100 nm. Other thicknesses that are lesser than or greater than the aforementioned thickness range can also be employed for the dielectric cap material.

Lithography and etching are then used to pattern the layer of gate dielectric material, the layer of gate conductor material, and if present, the layer of dielectric cap material. The remaining portion of the layer of gate dielectric material provides the gate dielectric material portion 18 of the gate structure 16, the remaining portion of the layer of gate conductor material provides the gate conductor material portion 20 of the gate structure 16 and, the remaining portion of the layer of dielectric cap material provides the dielectric cap 22 of the gate structure.

Lithography can include forming a photoresist (not shown) on the topmost surface of either the layer of dielectric cap material or the layer of gate conductor material, exposing the photoresist to a desired pattern of radiation, and then developing the exposed photoresist with a conventional resist developer to provide a patterned photoresist atop either the layer of dielectric cap material or the layer of gate conductor material. At least one etch is then employed which transfers the pattern from the patterned photoresist into the various material. In one embodiment, the etch used for pattern transfer may include a dry etch process such as, for example, reactive ion etching, plasma etching, ion beam etching or laser ablation. In another embodiment, the etch used for pattern transfer may include a wet chemical etchant such as, for example, KOH (potassium hydroxide). In yet another embodiment, a combination of a dry etch and a wet chemical etch may be used to transfer the pattern. After transferring the pattern into the material layers, the patterned photoresist can be removed utilizing a conventional resist stripping process such as, for example, ashing. In some embodiments, the patterned photoresist can be removed after transferring the pattern into the layer of dielectric cap material.

As is shown in the embodiment illustrated in FIG. 1, sidewall surfaces of the gate dielectric material portion 18, the gate conductor material portion 20 and, if present, the dielectric cap 22 are vertically coincident to (i.e., vertically aligned with) each other.

In a gate last process, a sacrificial gate structure can be formed at this point of the present application as gate structure 16, and then during a subsequent processing step the sacrificial gate structure can be replaced with a functional gate structure. The term “sacrificial gate structure” is used throughout the present application to denote a material that serves as a placeholder structure for a functional gate structure to be subsequently formed. In one embodiment, each gate structure includes a sacrificial gate structure. In yet another embodiment, a first set of gate structures can comprise a functional gate structure, while a second set of gate structures comprises a sacrificial gate structure. In such an embodiment, block mask technology can be used in forming the different gate structures.

In embodiments in which the gate structure 16 is a sacrificial gate structure (not shown in drawings), the sacrificial gate structure is formed by first providing a blanket layer of a sacrificial gate material on semiconductor material 14. The blanket layer of sacrificial gate material can be formed, for example, by chemical vapor deposition or plasma enhanced chemical vapor deposition. The thickness of the blanket layer of sacrificial gate material can be from 50 nm to 300 nm, although lesser and greater thicknesses can also be employed. The blanket layer of sacrificial gate material can include any material that can be selectively removed from the structure during a subsequently performed etching process. In one embodiment, the blanket layer of sacrificial gate material may be composed of polysilicon. In another embodiment of the present application, the blanket layer of sacrificial gate material may be composed of a metal such as, for example, Al, W, or Cu. After providing the blanket layer of sacrificial gate material, the blanket layer of sacrificial gate material can be patterned by lithography and etching so as to form the sacrificial gate structure.

FIG. 1 also shows the presence of first dielectric spacer 24 on each vertical sidewall surface of the gate structure 16. A base of the first dielectric spacer 24 is present on another portion of the semiconductor material 14. First dielectric spacer 24 can be formed by first providing a spacer material and then etching the spacer material. The spacer material may be composed of any dielectric spacer material including, for example, a dielectric oxide, dielectric nitride, and/or dielectric oxynitride. In one example, the spacer material used in providing the first dielectric spacer 24 may be composed of silicon dioxide or silicon nitride. The spacer material can be provided by a deposition process including, for example, chemical vapor deposition (CVD), plasma enhanced chemical vapor deposition (PECVD), or physical vapor deposition (PVD). The etching of the spacer material may comprise a dry etch process such as, for example, a reactive ion etch.

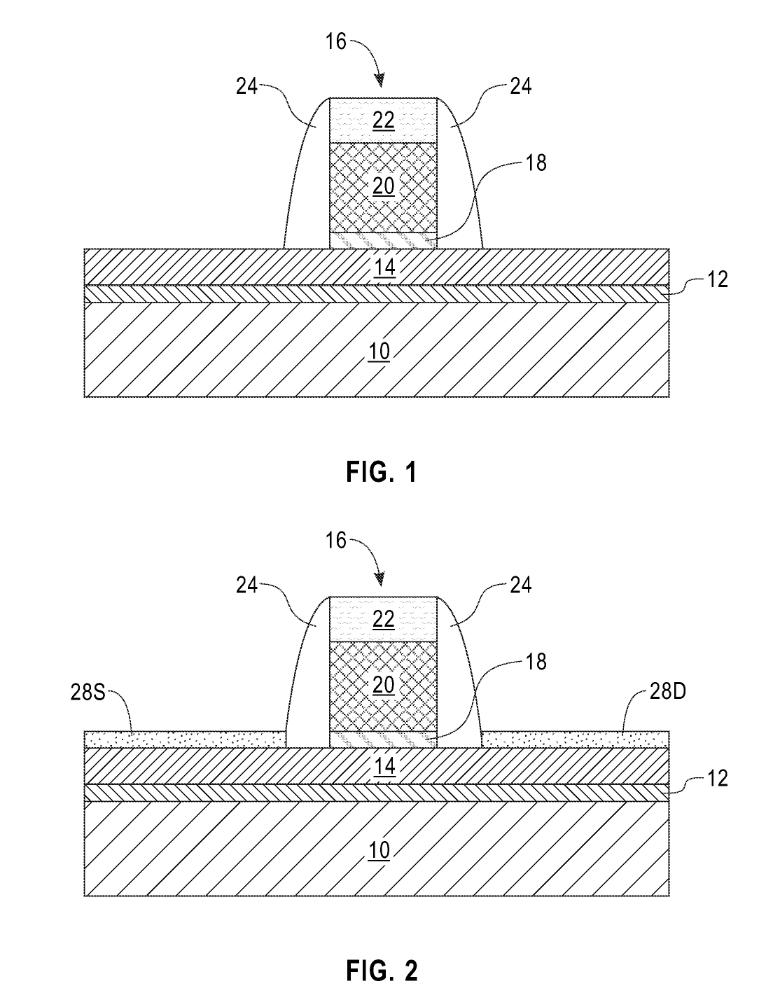

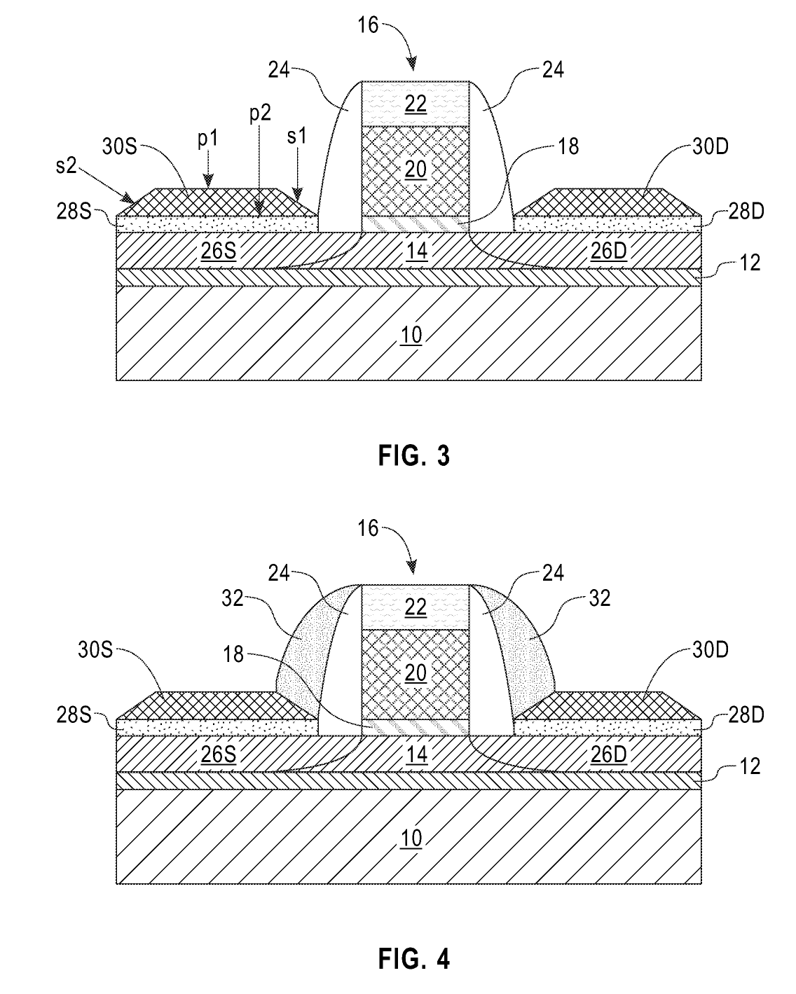

In some embodiments of the present application, the sacrificial gate structure can be now replaced prior to forming the structure shown in FIG. 2. In another embodiments, the sacrificial gate structure can be replaced after forming the structure shown in FIG. 3, 4 or 5.

Referring now to FIG. 2, there is illustrated the structure of FIG. 1 after forming a source-side phosphorus doped epitaxial semiconductor material portion 28S on one side of the gate structure 16, and a drain-side phosphorus doped epitaxial semiconductor material portion 28D on another side of the gate structure 16. Notably, the source-side phosphorus doped epitaxial semiconductor material portion 28S is formed on a second portion of the semiconductor material 14 and the drain-side phosphorus doped epitaxial semiconductor material portion 28D is formed on a third portion of the semiconductor material 14. As is shown, a sidewall portion of the source-side phosphorus doped epitaxial semiconductor material portion 28S and a sidewall portion of the drain-side phosphorus doped epitaxial semiconductor material portion 28D directly contact a sidewall surface of the first dielectric spacer 24.

The source-side phosphorus doped epitaxial semiconductor material portion 28S includes phosphorous and at least one semiconductor material. The at least one semiconductor material of the source-side phosphorus doped epitaxial semiconductor material portion 28S may include any of the semiconductor materials mentioned above for semiconductor material 14. In one embodiment of the present application, the at least one semiconductor material of the source-side phosphorus doped epitaxial semiconductor material portion 28S is a same semiconductor material as that of semiconductor material 14. In another embodiment, the at least one semiconductor material of the source-side phosphorus doped epitaxial semiconductor material portion 28S is a different semiconductor material than semiconductor material 14. For example, when semiconductor material 14 is comprised of silicon, than the source-side phosphorus doped epitaxial semiconductor material portion 28S may be comprised of SiGe.

The drain-side phosphorus doped epitaxial semiconductor material portion 28D includes phosphorous and at least one semiconductor material. The at least one semiconductor material of the drain-side phosphorus doped epitaxial semiconductor material portion 28D may include any of the semiconductor materials mentioned above for semiconductor material 14. In one embodiment of the present application, the at least one semiconductor material of the drain-side phosphorus doped epitaxial semiconductor material portion 28D is a same semiconductor material as that of semiconductor material 14. In another embodiment, the at least one semiconductor material of the drain-side phosphorus doped epitaxial semiconductor material portion 28D is a different semiconductor material than semiconductor material 14. For example, when semiconductor material 14 is comprised of silicon, than the drain-side phosphorus doped epitaxial semiconductor material portion 28D may be comprised of SiGe.

In accordance with the present application, the at least one semiconductor material of the source-side phosphorus doped epitaxial semiconductor material portion 28S is a same semiconductor material as that of the at least one semiconductor material of the drain-side phosphorus doped epitaxial semiconductor material portion 28D.

The source-side phosphorus doped epitaxial semiconductor material portion 28S and the drain-side phosphorus doped epitaxial semiconductor material portion 28D can be formed by an in-situ doped epitaxial growth process. In the embodiment illustrated, the source-side phosphorus doped epitaxial semiconductor material portion 28S and the drain-side phosphorus doped epitaxial semiconductor material portion 28D are formed by a bottom-up epitaxial growth process. As such, the source-side phosphorus doped epitaxial semiconductor material portion 28S and the drain-side phosphorus doped epitaxial semiconductor material portion 28D have an epitaxial relationship with that of the underlying surface of the semiconductor material portion.

The terms “epitaxial growth and/or deposition” and “epitaxially formed and/or grown” mean the growth of a semiconductor material on a deposition surface of a semiconductor material, in which the semiconductor material being grown has the same crystalline characteristics as the semiconductor material of the deposition surface. In an epitaxial deposition process, the chemical reactants provided by the source gasses are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed. For example, an epitaxial semiconductor material deposited on a {100} crystal surface will take on a {100} orientation. In some embodiments, epitaxial growth and/or deposition processes are selective to forming on semiconductor surface, and do not deposit material on dielectric surfaces, such as silicon dioxide or silicon nitride surfaces.

Examples of various epitaxial growth process apparatuses that are suitable for use in forming the source-side phosphorus doped epitaxial semiconductor material portion 28S and the drain-side phosphorus doped epitaxial semiconductor material portion 28D of the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition process for forming the source-side phosphorus doped epitaxial semiconductor material portion 28S and the drain-side phosphorus doped epitaxial semiconductor material portion 28D typically ranges from 550° C. to 900° C. Although higher temperature typically results in faster deposition, the faster deposition may result in crystal defects and film cracking.

A number of different sources may be used for the deposition of the source-side phosphorus doped epitaxial semiconductor material portion 28S and the drain-side phosphorus doped epitaxial semiconductor material portion 28D. In some embodiments, the gas source for the deposition of epitaxial semiconductor material include a silicon containing gas source, a germanium containing gas source, or a combination thereof. For example, an epitaxial Si layer may be deposited from a silicon gas source that is selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof. An epitaxial germanium layer can be deposited from a germanium gas source that is selected from the group consisting of germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, nitrogen, helium and argon can be used.

In addition to the above mentioned gases, the deposition of the source-side phosphorus doped epitaxial semiconductor material portion 28S and the drain-side phosphorus doped epitaxial semiconductor material portion 28D also includes a phosphorus-containing compound as a dopant. In one embodiment of the present application, the dopant gas employed in forming the source-side phosphorus doped epitaxial semiconductor material portion 28S and the drain-side phosphorus doped epitaxial semiconductor material portion 28D includes phosphine (PH₃). In one example, the epitaxial deposition of the source-side phosphorus doped epitaxial semiconductor material portion 28S and the drain-side phosphorus doped epitaxial semiconductor material portion 28D includes phosphine gas (PH₃) present in a ratio to silane (SiH₄) ranging from 0.00001% to 2%.

In one embodiment, phosphorus is present in the source-side phosphorus doped epitaxial semiconductor material portion 28S and the drain-side phosphorus doped epitaxial semiconductor material portion 28D in a concentration ranging from 1×10¹⁹ atoms/cm³ to 10²¹ atoms/cm³. In another embodiment, phosphorus is present in the source-side phosphorus doped epitaxial semiconductor material portion 28S and the drain-side phosphorus doped epitaxial semiconductor material portion 28D in a concentration ranging 1×10²⁰ atoms/cm³ to 8×10²⁰ atoms/cm³. The concentration of phosphorus within the source-side phosphorus doped epitaxial semiconductor material portion 28S can be equal to, greater than, or less than the concentration of phosphorus within the drain-side phosphorus doped epitaxial semiconductor material portion 28D.

In one embodiment of the present application, phosphorus can be uniformly present in the source-side phosphorus doped epitaxial semiconductor material portion 28S and/or the drain-side phosphorus doped epitaxial semiconductor material portion 28D. In another of the present application, phosphorus can be present as a gradient in the source-side phosphorus doped epitaxial semiconductor material portion 28S and/or the drain-side phosphorus doped epitaxial semiconductor material portion 28D.

In some embodiments of the present application, the source-side phosphorus doped epitaxial semiconductor material portion 28S and/or the drain-side phosphorus doped epitaxial semiconductor material portion 28D can be hydrogenated. When hydrogenated, a hydrogen source is used in conjunction with the other source gases and the amount of hydrogen that is present within the source-side phosphorus doped epitaxial semiconductor material portion 28S and/or the drain-side phosphorus doped epitaxial semiconductor material portion 28D can be from 1 atomic percent to 40 atomic percent. In another embodiment, carbon can be present in the source-side phosphorus doped epitaxial semiconductor material portion 28S and/or the drain-side phosphorus doped epitaxial semiconductor material portion 28D. When present, a carbon source (such as, for example, mono-methylsilane) is used in conjunction with the other source gases and carbon, C, can be present in the source-side phosphorus doped epitaxial semiconductor material portion 28S and/or the drain-side phosphorus doped epitaxial semiconductor material portion 28D in range from 0 atomic % to 4 atomic %.

The thickness of the source-side phosphorus doped epitaxial semiconductor material portion 28S and the drain-side phosphorus doped epitaxial semiconductor material portion 28D may range from 2 nm to 100 nm. In another embodiment, the thickness of the source-side phosphorus doped epitaxial semiconductor material portion 28S and the drain-side phosphorus doped epitaxial semiconductor material portion 28D ranges from 5 nm to 50 nm. The source-side phosphorus doped epitaxial semiconductor material portion 28S may have a thickness that is equal to, greater than, or less than the thickness of the drain-side phosphorus doped epitaxial semiconductor material portion 28D.

Referring now to FIG. 3, there is illustrated the structure shown in FIG. 2 after forming a source-side arsenic doped epitaxial semiconductor material portion 30S on an uppermost surface of the source-side phosphorus doped epitaxial semiconductor material portion 28S and on one side of the gate structure 16, and a drain-side arsenic doped epitaxial semiconductor material portion 30D on an uppermost surface of the drain-side phosphorus doped epitaxial semiconductor material portion 28D and on another side of the gate structure 16 and annealing. The anneal causes diffusion of dopant, i.e., phosphorus, from the source-side phosphorus doped epitaxial semiconductor material portion 28S downwards into the second portion of the semiconductor material 14 and formation of a source region 26S, and diffusion of dopant, i.e., phosphorus, from the drain-side phosphorus doped epitaxial semiconductor material portion 28D downwards through into the third portion of the semiconductor material 14 and formation of a drain region 26D. Little or no diffusion of arsenic occurs from the source-side arsenic doped epitaxial semiconductor material portion 30S and the drain-side arsenic doped epitaxial semiconductor material portion 30D.

The source-side arsenic doped epitaxial semiconductor material portion 30S includes arsenic and at least one semiconductor material. The at least one semiconductor material of the source-side arsenic doped epitaxial semiconductor material portion 30S may include any of the semiconductor materials mentioned above for semiconductor material 14. In one embodiment of the present application, the at least one semiconductor material of the source-side arsenic doped epitaxial semiconductor material portion 30S is a same semiconductor material as that of semiconductor material 14. In another embodiment, the at least one semiconductor material of the source-side arsenic doped epitaxial semiconductor material portion 30S is a different semiconductor material than semiconductor material 14. For example, when semiconductor material 14 is comprised of silicon, than the source-side arsenic doped epitaxial semiconductor material portion 30S may be comprised of SiGe. The source-side arsenic doped epitaxial semiconductor material portion 30S may comprise a same or different semiconductor material than the source-side phosphorus doped epitaxial semiconductor material portion 28S.

The drain-side arsenic doped epitaxial semiconductor material portion 30D includes arsenic and at least one semiconductor material. The at least one semiconductor material of the drain-side arsenic doped epitaxial semiconductor material portion 30D may include any of the semiconductor materials mentioned above for semiconductor material 14. In one embodiment of the present application, the at least one semiconductor material of the drain-side arsenic doped epitaxial semiconductor material portion 30D is a same semiconductor material as that of semiconductor material 14. In another embodiment, the at least one semiconductor material of the drain-side arsenic doped epitaxial semiconductor material portion 30D is a different semiconductor material than semiconductor material 14. For example, when semiconductor material 14 is comprised of silicon, than the drain-side arsenic doped epitaxial semiconductor material portion may be comprised of SiGe. The drain-side arsenic doped epitaxial semiconductor material portion 30D may comprise a same or different semiconductor material than the drain-side phosphorus doped epitaxial semiconductor material portion 28D.

The at least one semiconductor material of the source-side arsenic doped epitaxial semiconductor material portion 30S is a same semiconductor material as that of the at least one semiconductor material of the drain-side arsenic doped epitaxial semiconductor material portion 30D.

The source-side arsenic doped epitaxial semiconductor material portion 30S and the drain-side arsenic doped epitaxial semiconductor material portion 30D can be formed by an in-situ doped epitaxial growth process, as mentioned above in forming the source-side phosphorus doped epitaxial semiconductor material portion 28S and the drain-side phosphorus doped epitaxial semiconductor material portion 28D.

Since an epitaxial growth process is used in forming the source-side arsenic doped epitaxial semiconductor material portion 30S and the drain-side arsenic doped epitaxial semiconductor material portion 30D, the source-side arsenic doped epitaxial semiconductor material portion 30S has a same crystal orientation as that of the source-side phosphorus doped epitaxial semiconductor material portion 28S, while the drain-side arsenic doped epitaxial semiconductor material portion 30D has a same crystal orientation as that of the drain-side phosphorus doped epitaxial semiconductor material portion 28D.

The source gases, and other gases (but not the dopant) as well as conditions mentioned above in forming the source-side phosphorus doped epitaxial semiconductor material portion 28S and the drain-side phosphorus doped epitaxial semiconductor material portion 28D can be used here in forming the source-side arsenic doped epitaxial semiconductor material portion 30S and the drain-side arsenic doped epitaxial semiconductor material portion 30D.

The deposition of the source-side arsenic doped epitaxial semiconductor material portion 30S and the drain-side arsenic doped epitaxial semiconductor material portion 30D also includes an arsenic-containing compound as a dopant. In one embodiment of the present application, the dopant gas employed in forming the source-side arsenic doped epitaxial semiconductor material portion 30S and the drain-side arsenic doped epitaxial semiconductor material portion 30D includes arsine (AsH₃). In one example, the epitaxial deposition of the source-side arsenic doped epitaxial semiconductor material portion 30S and the drain-side arsenic doped epitaxial semiconductor material portion 30D includes arsine gas (AsH₃) present in a ratio to silane (SiH₄) ranging from 0.00001% to 2%.

In one embodiment, arsenic is present in the source-side arsenic doped epitaxial semiconductor material portion 30S and the drain-side arsenic doped epitaxial semiconductor material portion 30D in a concentration ranging from 1×10¹⁹ atoms/cm³ to 10²¹ atoms/cm³. In another embodiment, arsenic is present in the source-side arsenic doped epitaxial semiconductor material portion 30S and the drain-side arsenic doped epitaxial semiconductor material portion 30D in a concentration ranging 1'10²⁰ atoms/cm³ to 8×10²⁰ atoms/cm³. The concentration of arsenic within the source-side arsenic doped epitaxial semiconductor material portion 30S can be equal to, greater than, or less than the concentration of arsenic within the drain-side arsenic doped epitaxial semiconductor material portion 28D.

In one embodiment of the present application, arsenic can be uniformly present in the source-side arsenic doped epitaxial semiconductor material portion 30S and/or the drain-side arsenic doped epitaxial semiconductor material portion 30D. In another of the present application, arsenic can be present as a gradient in the source-side arsenic doped epitaxial semiconductor material portion 30S and/or the drain-side arsenic doped epitaxial semiconductor material portion 30D.

In some embodiments of the present application, the source-side arsenic doped epitaxial semiconductor material portion 30S and/or the drain-side arsenic phosphorus doped epitaxial semiconductor material portion 30D can be hydrogenated. When hydrogenated, a hydrogen source is used in conjunction with the other source gases and the amount of hydrogen that is present within the source-side arsenic doped epitaxial semiconductor material portion 30S and/or the drain-side arsenic doped epitaxial semiconductor material portion 30D can be from 1 atomic percent to 40 atomic percent. In another embodiment, carbon can be present in the the source-side arsenic doped epitaxial semiconductor material portion 30S and/or the drain-side arsenic doped epitaxial semiconductor material portion 30D. When present, a carbon source (such as, for example, mono-methylsilane) is used in conjunction with the other source gases and carbon, C, can be present in the source-side arsenic doped epitaxial semiconductor material portion 30S and/or the drain-side arsenic doped epitaxial semiconductor material portion 30D in range from 0 atomic % to 4 atomic %.

The thickness of the source-side arsenic doped epitaxial semiconductor material portion 30S and the drain-side arsenic doped epitaxial semiconductor material portion 30D may range from 2 nm to 100 nm. In another embodiment, the thickness of the source-side arsenic doped epitaxial semiconductor material portion 30S and the drain-side arsenic doped epitaxial semiconductor material portion 30D ranges from 5 nm to 50 nm. The source-side arsenic doped epitaxial semiconductor material portion 30S may have a thickness that is equal to, greater than, or less than the thickness of the drain-side arsenic doped epitaxial semiconductor material portion 30D.

In some embodiments of the present application, the source-side arsenic doped epitaxial semiconductor material portion 30S and the drain-side arsenic doped epitaxial semiconductor material portion 30D have a shape of a convex quadrilateral with at least one pair of parallel sides (i.e., trapezoid). The parallel sides (p1, p2) are called the bases of the trapezoid and the other two sides are called the legs or the lateral sides (s1, s2). As is shown, the lateral sides s1, s2 of the source-side arsenic doped epitaxial semiconductor material portion 30S and the drain-side arsenic doped epitaxial semiconductor material portion 30D do not form right angles to the two parallel sides p1, p2.

In some embodiments of the present application, the source-side arsenic doped epitaxial semiconductor material portion 30S and the drain-side arsenic doped epitaxial semiconductor material portion 30D have a rectangular shape with a bottommost and topmost surface that are entirely planar and span from one sidewall of the first dielectric spacer 24 to a sidewall of a neighboring first dielectric spacer 24.

The source-side phosphorus doped epitaxial semiconductor material portion 28S and the source-side arsenic doped epitaxial semiconductor material portion 30S provide a raised source region of the present application. The drain-side phosphorus doped epitaxial semiconductor material portion 28D and the drain-side arsenic doped epitaxial semiconductor material portion 30D provide a raised drain region of the present application.

After forming the source-side arsenic doped epitaxial semiconductor material portion 30S and the drain-side arsenic doped epitaxial semiconductor material portion 30D, an anneal is performed. The anneal causes diffusion of dopant, i.e., phosphorus, from the source-side phosphorus doped epitaxial semiconductor material portion 28S downwards into the second portion of the semiconductor material and formation of a source region 26S, and diffusion of dopant, phosphorus, from the drain-side phosphorus doped epitaxial semiconductor material portion 28D downwards into the third portion of the semiconductor material 14 and formation of a drain region 26D. The anneal process used in forming the source region 26A and the drain region 26D may be a rapid thermal anneal, furnace annealing, flash annealing, laser annealing or any suitable combination of those techniques. The annealing temperature may range from 600° to 1300° C. with an anneal time ranging from a millisecond to 30 minutes. In one embodiment, the annealing is done by a flash anneal process at about 1200° C. for twenty (20) milliseconds.

Notably, FIG. 3 shows a semiconductor structure in accordance with an embodiment of the present application that includes a gate structure 16 located on a first portion of a semiconductor material 14. The structure also includes a raised source region located on a second portion of the semiconductor material 14 and on one side of the gate structure 16, wherein the raised source region comprises, from bottom to top, a source-side phosphorus doped epitaxial semiconductor material portion 28S and a source-side arsenic doped epitaxial semiconductor material portion 30D. The structure further includes a raised drain region located on a third portion of the semiconductor material 14 and on another side of the gate structure 16, wherein the raised drain region comprises from, bottom to top, a drain-side phosphorus doped epitaxial semiconductor material portion 28D and a drain-side arsenic doped epitaxial semiconductor material portion 30D.

Referring now to FIG. 4, there is illustrated the structure of FIG. 3 after forming a second dielectric spacer 32 on each side of the gate structure 16. As is shown, each second dielectric spacer 32 has a base in direct contact with a surface (e.g., a lateral side s1, s2) of the source-side arsenic doped epitaxial semiconductor material portion 30S and the drain-side arsenic doped epitaxial semiconductor material portion 30D. As is also shown, each second dielectric spacer 32 has a sidewall in direct contact with a sidewall of the first dielectric spacer 24. The second dielectric spacer 32 comprises one of the dielectric spacer materials mentioned above in providing first dielectric spacer 24. In one embodiment, the second dielectric spacer 32 comprises a same dielectric spacer material as used in providing the first dielectric spacer 24. In another embodiment, the second dielectric spacer 32 comprises a different dielectric spacer material as used in providing the first dielectric spacer 24. The second dielectric spacer 32 can be formed utilizing the processing steps mentioned above in forming the first dielectric spacer 24.

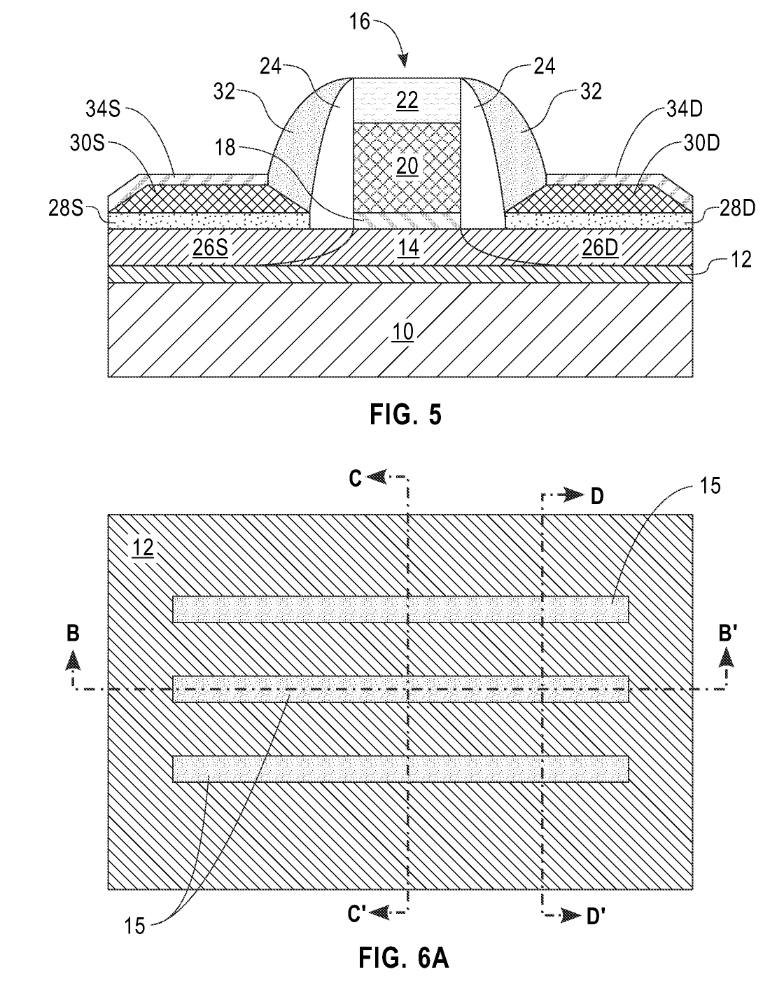

Referring now to FIG. 5, there is a cross sectional view of the structure shown in FIG. 4 after forming a source-side metal semiconductor alloy 34S on a surface of the source-side arsenic doped epitaxial semiconductor material portion 30S and a drain-side metal semiconductor alloy 34D is located on a surface of the drain-side arsenic doped epitaxial semiconductor material portion 30D. In some embodiments, no metal semiconductor alloy is present on lateral sidewalls s1, s2 of the source-side arsenic doped epitaxial semiconductor material portion 30S and the drain-side arsenic doped epitaxial semiconductor material portion 30D.

The source-side metal semiconductor alloy 34S and the drain-side metal semiconductor alloy 34D can be formed by first depositing a metal semiconductor alloy forming metal such as for example, Ni, Pt, Co, and alloys such as NiPt, on a surface source-side arsenic doped epitaxial semiconductor material portion 30S and on a surface of the drain-side arsenic doped epitaxial semiconductor material portion 30D. An optional diffusion barrier layer such as, for example, TiN or TaN, can be deposited atop the metal semiconductor alloy forming metal. An anneal is then performed that causes reaction between the metal semiconductor alloy forming metal and the epitaxial semiconductor material within source-side arsenic doped epitaxial semiconductor material portion 30S and the drain-side arsenic doped epitaxial semiconductor material portion 30D. After annealing, any unreactive metal including the diffusion barrier layer can be removed. When Ni is used the NiSi phase is formed due to its low resistivity. For example, formation temperatures include 400° C.-600° C. In the present application, the source-side metal semiconductor alloy 34S and the drain-side metal semiconductor alloy 34D includes a same metal semiconductor alloy forming metal.

The source-side metal semiconductor alloy 34S that is formed includes a metal semiconductor alloy forming metal, a semiconductor material as present within the source-side arsenic doped epitaxial semiconductor material portion 30S, and also arsenic. The source-side metal semiconductor alloy 34D that is formed includes a metal semiconductor alloy forming metal, a semiconductor material as present within the drain-side arsenic doped epitaxial semiconductor material portion 30D, and also arsenic.

The thickness of the source-side metal semiconductor alloy 34S and the drain-side metal semiconductor alloy 34D may range from 2 nm to 50 nm. In another embodiment, the thickness of the source-side metal semiconductor alloy 34S and the drain-side metal semiconductor alloy 34D ranges from 5 nm to 25 nm. The source-side metal semiconductor alloy 34S may have a thickness that is equal to, greater than, or less than the thickness of the drain-side metal semiconductor alloy 34D.

At this point of the present application, a dielectric material can be formed atop the structure shown in FIG. 5, and then via contacts includes a via contact metal such as, for example, Al, W, Cu, and alloys thereof, can be formed within the dielectric material. In embodiments in which the gate structure 14 is a sacrificial gate structure, the sacrificial gate structure can be removed forming a gate cavity in the space previously occupied by the sacrificial gate structure. A functional gate structure can then be formed in the gate cavity. In some embodiments in which a sacrificial gate structure is replaced with a functional gate structure, the gate dielectric material portion is present only within a bottom portion of each gate cavity. In another embodiment of the present application (not shown), the gate dielectric material portion includes vertically extending portions that directly contact exposed vertical sidewalls of each first dielectric spacer 24 defining the width of each gate cavity. In such an embodiment, each vertically extending portion of gate dielectric material portion laterally separates gate conductor material portion 20 from the vertical sidewall surfaces of the first dielectric spacer 24.

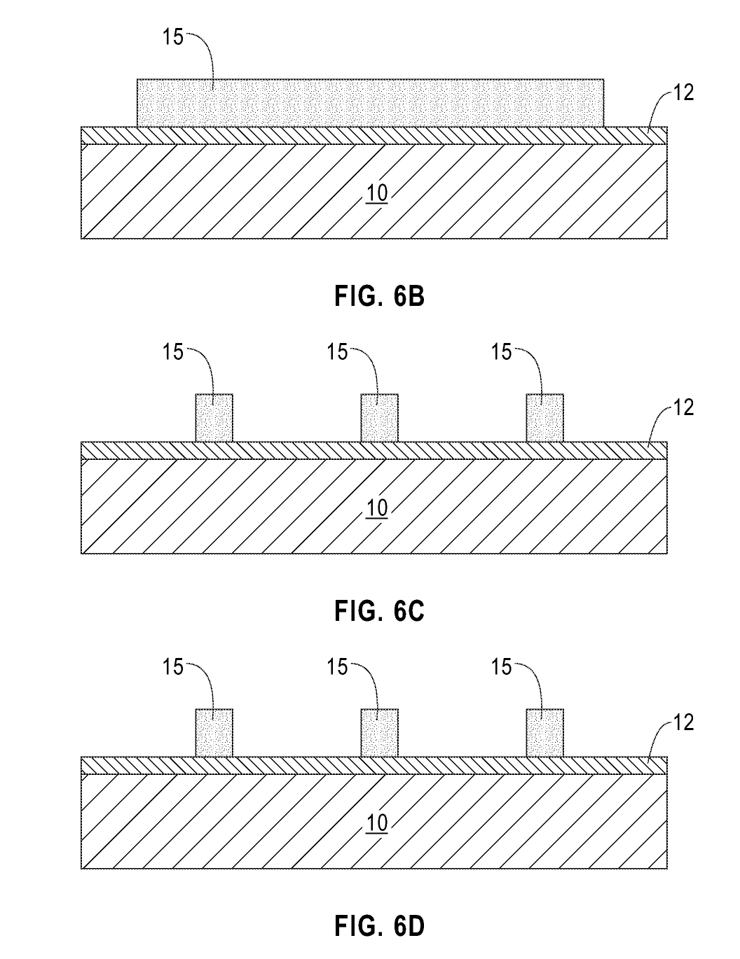

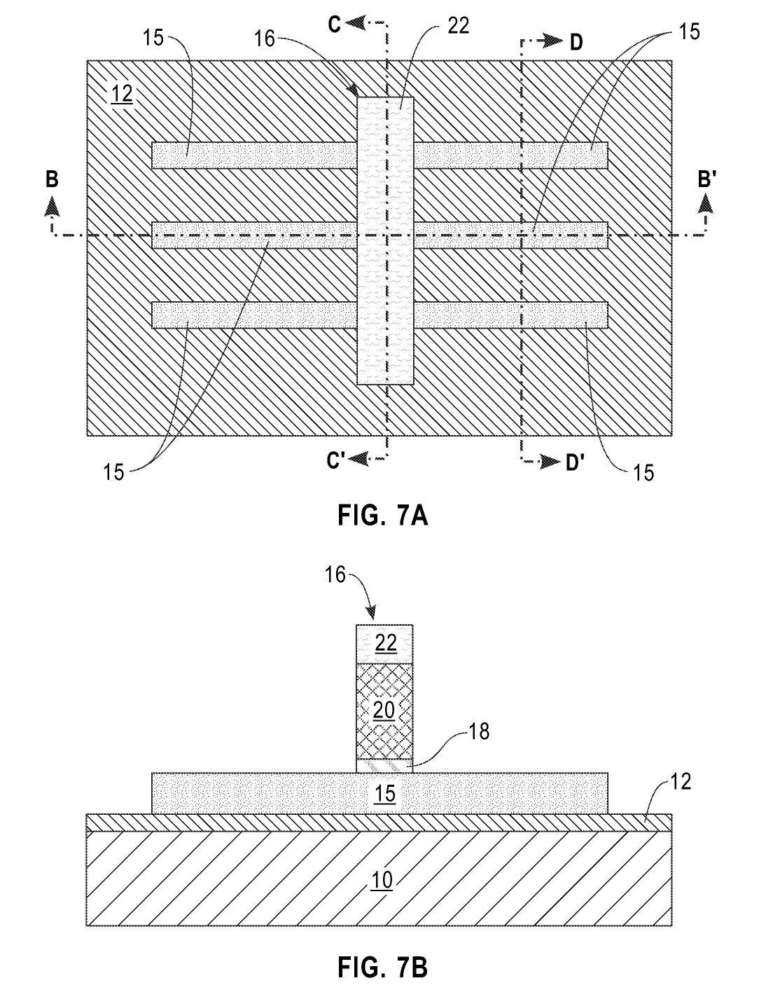

Reference is now made to FIGS. 6A-13C which illustrate embodiments of the present application in which finFETs containing a raised source region and a raised drain region each including a material stack, from bottom to top, of a phosphorus doped epitaxial semiconductor material portion and an arsenic doped epitaxial semiconductor material portion is formed. In the FinFET embodiments to follow, the starting substrate is an SOI substrate including from bottom to top, handle substrate 10, insulator layer 12, and semiconductor material 14 as described above. In FIGS. 6A-13C and in the following discussion, elements that are the same as those described above in FIGS. 1-5 are described with like reference numeral. As such, the above description of various elements (including composition, thickness and processes) that can be used here in FIGS. 6A-13C is incorporated herein by reference.

In the top down views shown in FIGS. 6A, 7A, 8A, 9A, 10A, 11A, 12A and 13A different vertical cross-sectional views along various planes are illustrated. Notably, the different vertical cross-sectional views along various planes include: B-B′ which is through a plane in which an semiconductor fin is present, and C-C′ through a plane perpendicular to each semiconductor fin and in which a gate structure will be subsequently formed or is present, and D-D′ through a plane perpendicular to each semiconductor fin and located on a side of the gate structure in which at least a raised drain region of the present application will be subsequently formed or is present. Although no cross sectional view is shown on the side in which at least the raised source region is formed, such a cross sectional view would be identical to D-D′.

Also in the drawings that follow, no fin cap is present atop each semiconductor fin that is formed. However, and in some embodiments, a layer of hard mask material such, as for example, silicon dioxide and/or silicon nitride, can be deposited on the exposed surface of the semiconductor material 14 prior to forming each semiconductor fin. During the formation of the semiconductor fins, a portion of the hard mask provides a fin cap on a topmost surface of each fin. In such a structure, the gate dielectric material portion to be subsequently formed is present only along the vertical sidewalls of each semiconductor fin. In the embodiment that is illustrated, no fin cap is present and as such, the gate dielectric material portion is present along the vertical sidewalls and on a topmost surface of each semiconductor fin.

Further in the description that follows, and in the drawings which correspond to the following discussion, like elements as described in the embodiment illustrated in FIGS. 1-5 which can also be used here for the finFET embodiments are described using like reference numerals.

Referring now to FIGS. 6A, 6B, 6C and 6D, there are shown a semiconductor structure containing a plurality of semiconductor fins 15 located on an insulator layer 12 of an SOI substrate in accordance with an embodiment of the present application. As is shown, the insulator layer 12 is located on handle substrate 10.

As is also shown, each semiconductor fin of the plurality of semiconductor fins 15 is spaced apart from its nearest neighboring semiconductor fin(s) 15. Also, each semiconductor fin of the plurality of semiconductor fins 15 is oriented parallel to each other. Further each semiconductor fin of the plurality of semiconductor fins 15 has a bottommost surface in direct contact with a topmost surface of the insulator layer 12. Each semiconductor fin of the plurality of fins 15 comprises a same semiconductor material as that of semiconductor material 14 described above.

While the present application is illustrated with a plurality of semiconductor fins 15, embodiments in which a single semiconductor fin 15 is employed in lieu of a plurality of semiconductor fins 15 are expressly contemplated herein.

The semiconductor structure shown in FIGS. 6A, 6B, 6C and 6D can be formed by lithography and etching. Lithography can include forming a photoresist (not shown) on the topmost surface of the semiconductor material 14, exposing the photoresist to a desired pattern of radiation, and then developing the exposed photoresist with a conventional resist developer to provide a patterned photoresist atop the semiconductor material 14. At least one etch is then employed which transfers the pattern from the patterned photoresist into the semiconductor material 14 utilizing the underlying insulator layer 12 as an etch stop. In one embodiment, the etch used for pattern transfer may include a dry etch process such as, for example, reactive ion etching, plasma etching, ion beam etching or laser ablation. In another embodiment, the etch used for pattern transfer may include a sidewall image transfer (SIT) process. After transferring the pattern into the semiconductor material 14, the patterned photoresist can be removed utilizing a conventional resist stripping process such as, for example, ashing.

As used herein, a “semiconductor fin” refers to a contiguous structure including a semiconductor material and including a pair of vertical sidewalls that are parallel to each other. As used herein, a surface is “vertical” if there exists a vertical plane from which the surface does not device by more than three times the root mean square roughness of the surface.

In one embodiment of the present application, each semiconductor fin 15 has a height from 10 nm to 100 nm, and a width from 4 nm to 30 nm. In another embodiment of the present application, each semiconductor fin 15 has a height from 15 nm to 50 nm, and a width from 5 nm to 12 nm.

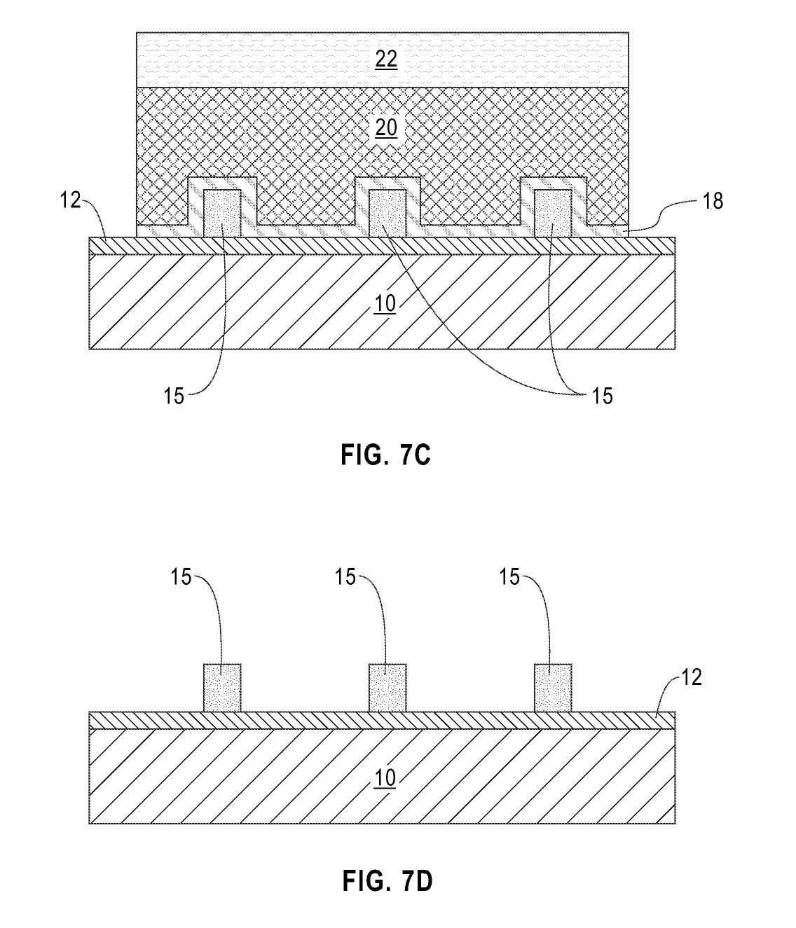

Referring now to FIGS. 7A, 7B, 7C and 7D, there are shown various views of the semiconductor structure shown in FIGS. 6A, 6B 6C and 6D after formation of a gate structure 16 that is orientated perpendicular to and that straddles each semiconductor fin 15. Although a single gate structure is shown, a plurality of gate structures can be formed in which each gate structure of the plurality of gate structures is spaced apart from one another, straddles each semiconductor fin 15 and is orientated perpendicular to each semiconductor fin 15.

The gate structure 16 can include a functional gate structure or a sacrificial gate structure, both of which have been previously described in this application. In the embodiment illustrated in FIGS. 7A, 7B, 7C and 7D, the gate structure 16 is a functional gate structure that includes a gate dielectric material portion 18 and a gate conductor material portion 20. An optional dielectric cap 22 can be located atop the gate conductor material portion 20. When a sacrificial gate structure is employed, the sacrificial gate structure can be replaced with a functional gate structure any time after the source and drain regions have been defined within the semiconductor fins.

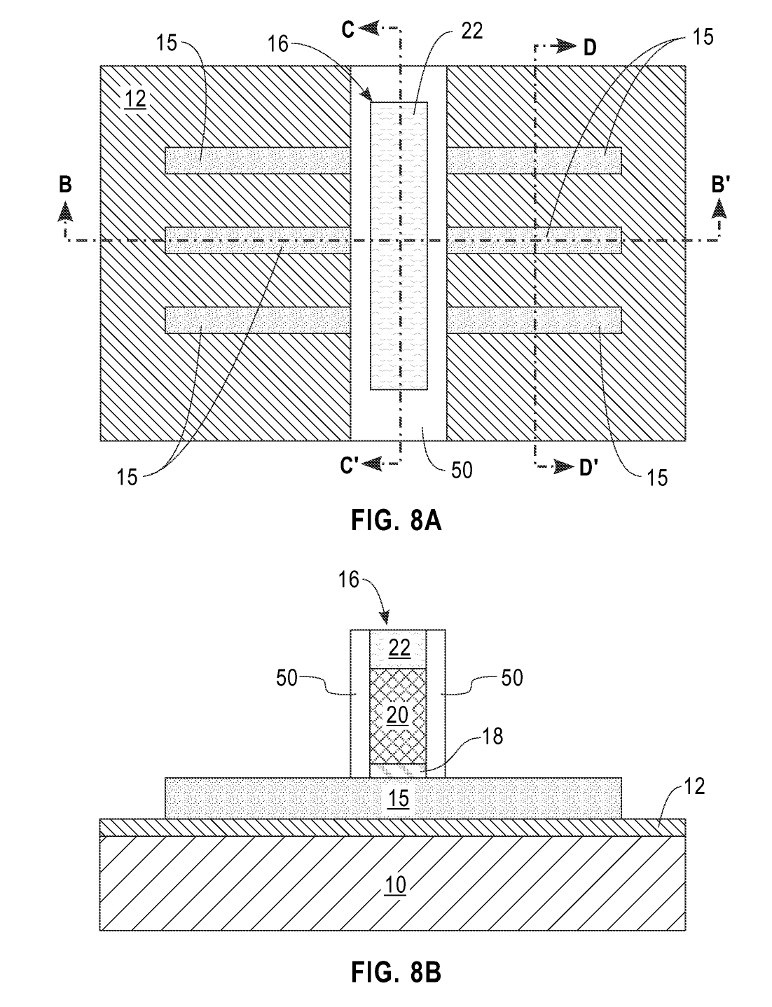

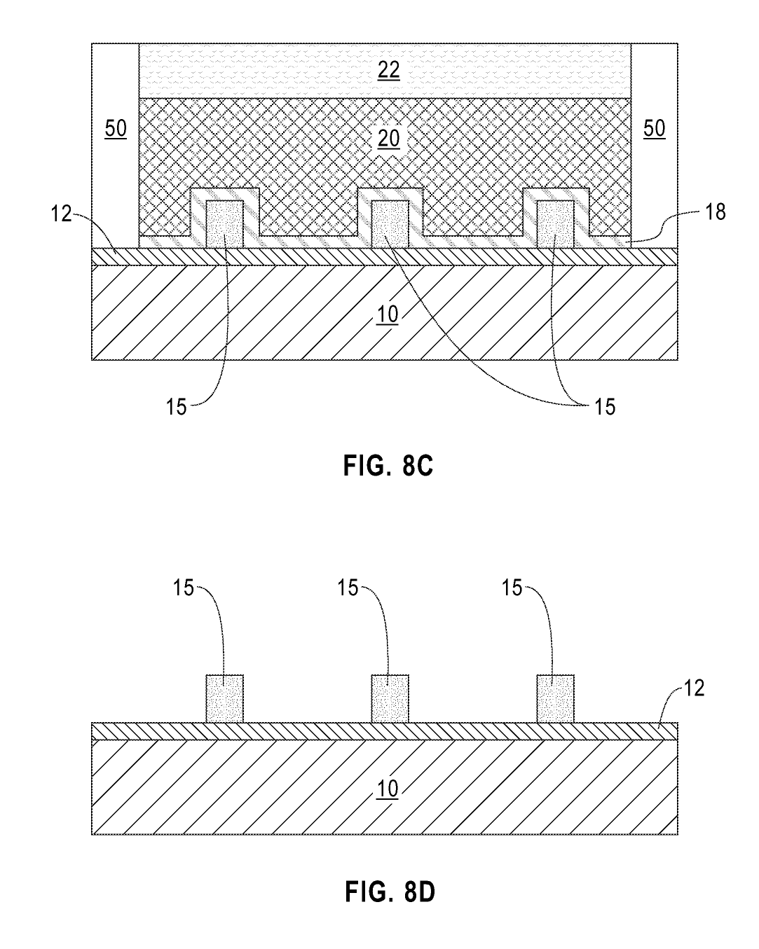

Referring now to FIGS. 8A, 8B, 8C and 8E, there are illustrated various views of the semiconductor structure shown in FIGS. 7A, 7B, 7C, and 7D after forming a gate spacer 50. Gate spacer 50 can include one of the spacer materials used in providing the first dielectric spacer 24 described hereinabove. Also, the gate spacer 50 can be formed utilizing the technique mentioned above in forming the first dielectric spacer 24. Note gate spacer 50 is located on the vertical sidewalls of the gate region 16.

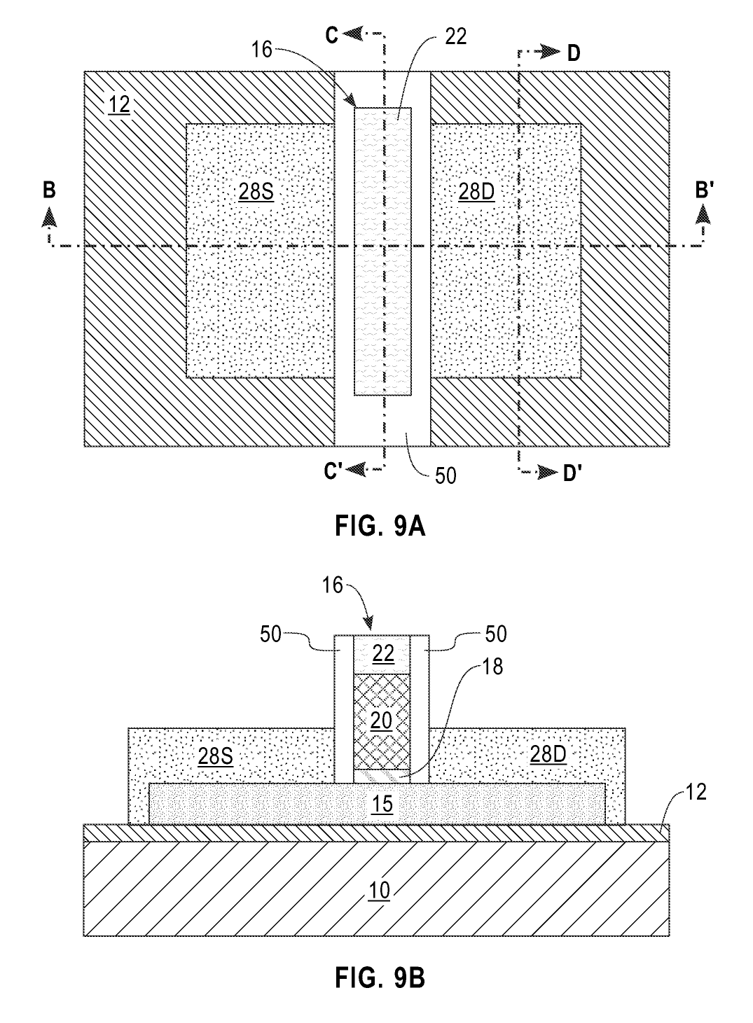

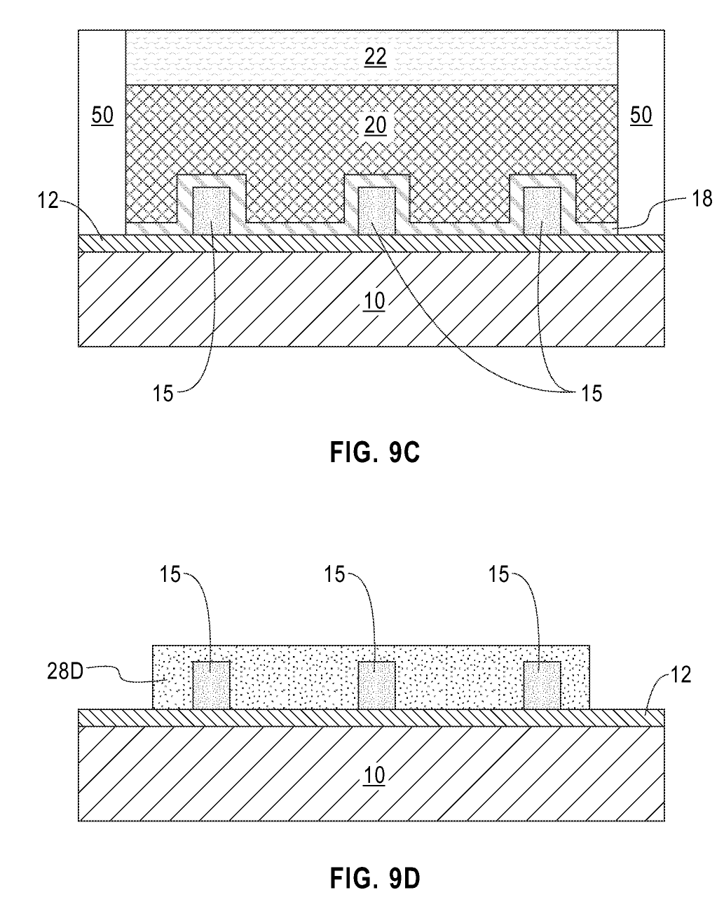

Referring now to FIGS. 9A, 9B, 9C, and 9D, there are show various views of the structure shown in FIGS. 8A, 8B, 8C and 8D after forming a source-side phosphorus doped epitaxial semiconductor material portion 28S on one side of the gate structure 16 and a drain-side phosphorus doped epitaxial semiconductor material portion 28D on another side of the gate structure 16. The source-side phosphorus doped epitaxial semiconductor material portion 28S is epitaxially grown from the sidewalls and from the topmost surface of each semiconductor fin 15, and the drain-side phosphorus doped epitaxial semiconductor material portion 28D is epitaxially grown from the sidewalls and from the topmost surface of each semiconductor fin 15. As shown in FIG. 9D, the drain-side phosphorus doped epitaxial semiconductor material portion 28D is located between each semiconductor fin 15. As a consequence, the drain-side phosphorus doped epitaxial semiconductor material portion 28D merges each semiconductor fin 15 on one side of the gate region 50. Similarly, the source-side phosphorus doped epitaxial semiconductor material portion 28S is located between each semiconductor fin 15. As a consequence, the source-side phosphorus doped epitaxial semiconductor material portion 28S merges each semiconductor fin 15 on another side of the gate region 50.

In the embodiment illustrated, both the source-side phosphorus doped epitaxial semiconductor material portion 28S and the drain-side phosphorus doped epitaxial semiconductor material portion 28D have a topmost surface that is planar, i.e., flat. In this embodiment, the flat topmost surface of the source-side phosphorus doped epitaxial semiconductor material portion 28S and the flat topmost surface drain-side phosphorus doped epitaxial semiconductor material portion 28D can be achieved by over filling the epitaxial semiconductor material above each semiconductor fin. During the merge process, <111> bound diamond shaped epitaxy is grown around each semiconductor fin. Once the diamonds merge, <100> planes form between the diamonds, the epitaxial growth rate is much faster, resulting in a smoothed surface.

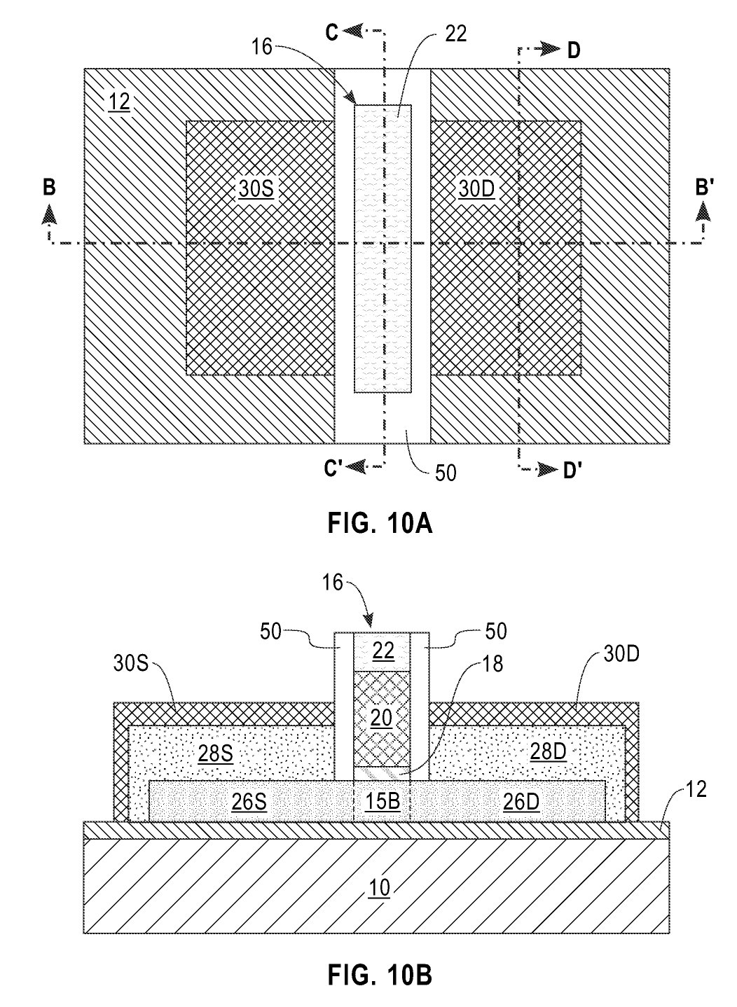

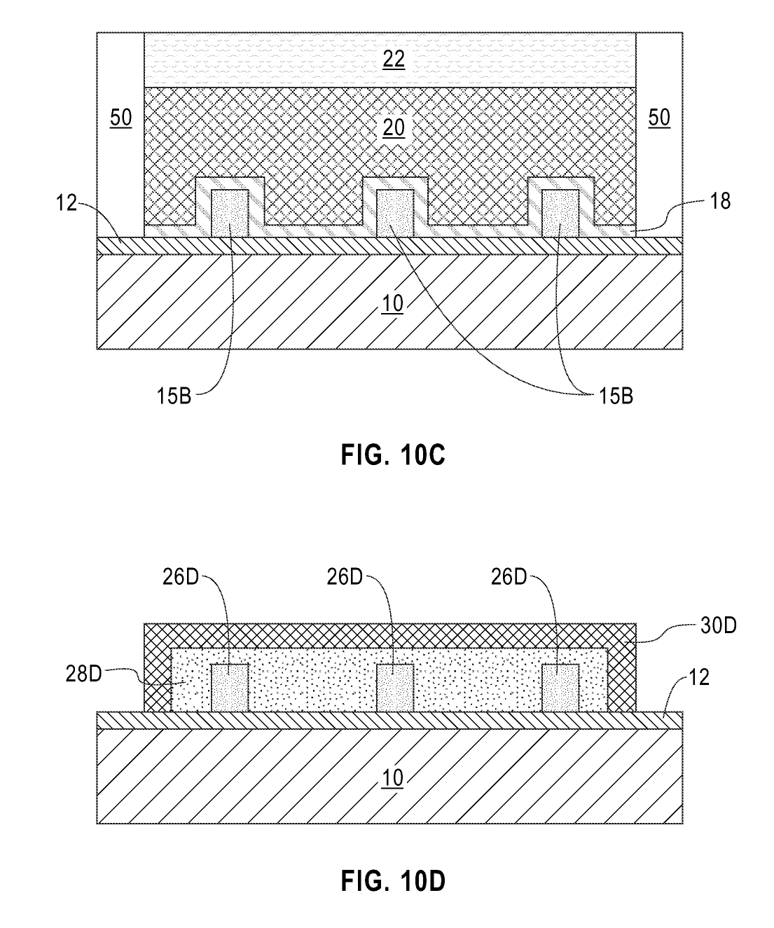

Referring to FIGS. 10A, 10B, 10C and 10D, there is shown various views of the semiconductor structure shown in FIGS. 9A, 9B, 9C and 9D after forming a source-side arsenic doped epitaxial semiconductor material portion 30S on one side of the gate structure 16 and on the source-side phosphorus doped epitaxial semiconductor material portion 28 and a drain-side arsenic doped epitaxial semiconductor material portion 30D on another side of the gate structure 16 and on the drain-side phosphorus doped epitaxial semiconductor material portion 30D and annealing. The annealing forms a source region 26S in a portion of each semiconductor fin 15 and on one side of the gate structure 16 and a drain region 26D in another portion of each semiconductor fin 15 and on another side of the gate structure 16.

In the embodiment illustrated, both the source-side arsenic doped epitaxial semiconductor material portion 30S and the drain-side arsenic doped epitaxial semiconductor material portion 30D have a topmost surface that is planar, i.e., flat.

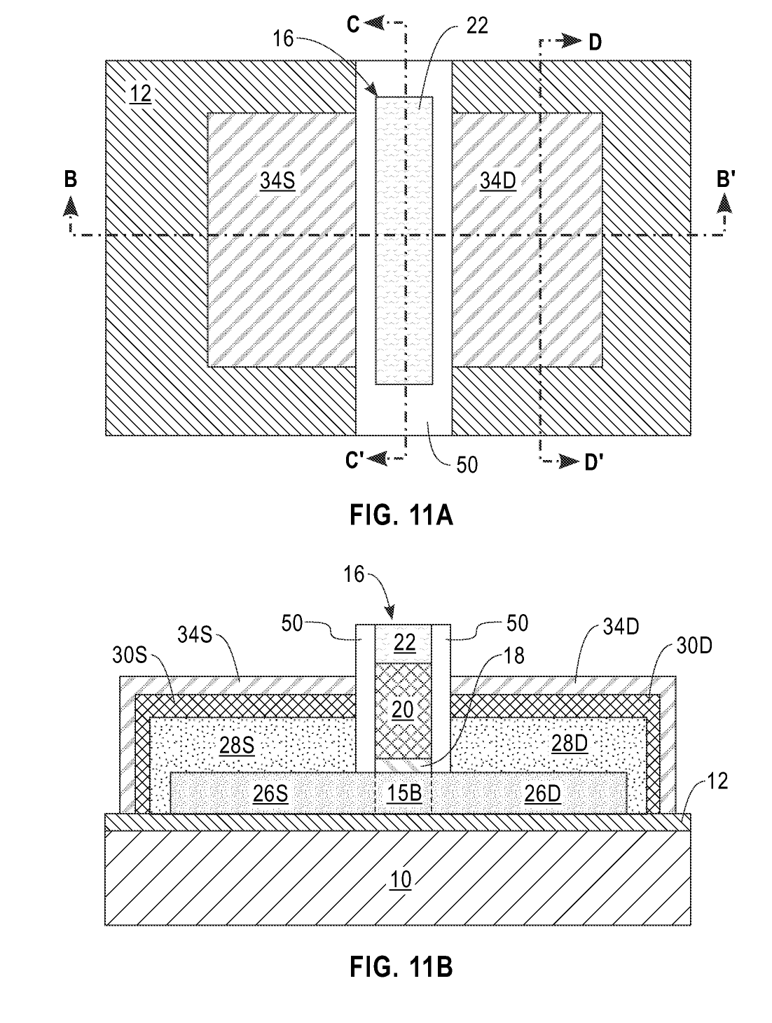

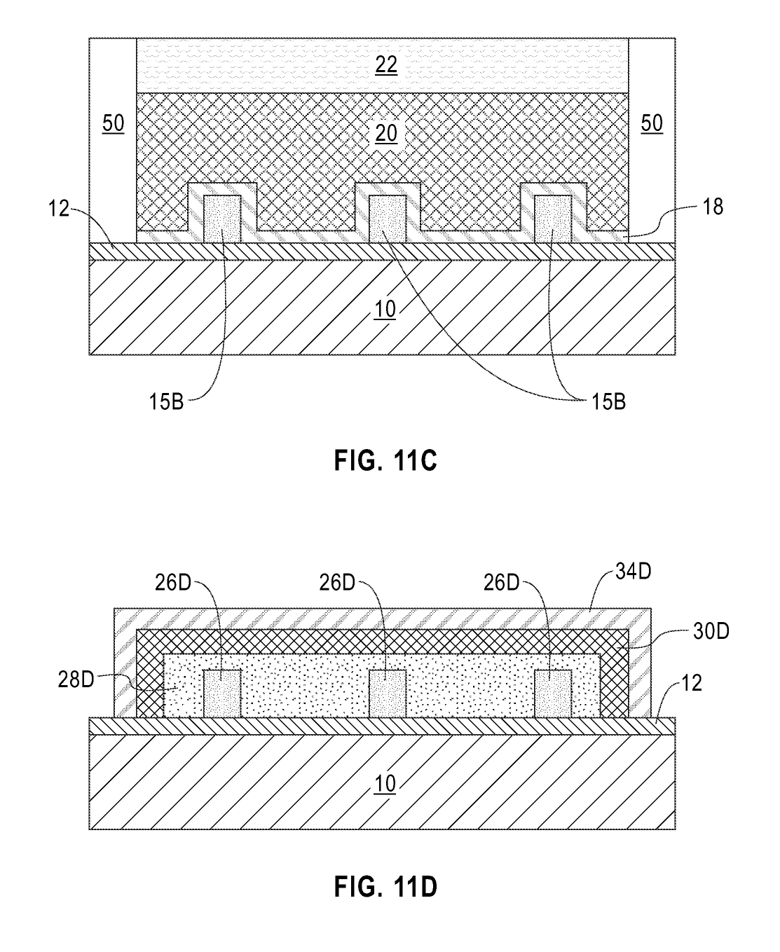

Referring to FIGS. 11A, 11B, 11C and 11D, there is shown various views of the semiconductor structure shown in FIGS. 10A, 10B, 10C and 10D after forming a source-side metal semiconductor alloy 34S on one side of the gate structure 16 and on the source-side arsenic doped epitaxial semiconductor material portion 30S and a drain-side metal semiconductor alloy 34D on another side of the gate structure 16 and on the drain-side arsenic doped epitaxial semiconductor material portion 30D. The anneal causes diffusion of dopant, i.e., phosphorus, from the source-side phosphorus doped epitaxial semiconductor material portion 28S downwards into a portion of each semiconductor fin 15 forming source region 26S, and diffusion of dopant, i.e., phosphorus, from the drain-side phosphorus doped epitaxial semiconductor material portion 28D downwards into another portion of each semiconductor fin 15 forming drain region 26D. The portion of the semiconductor fin that is located between the source region 26S, and the drain region 26D and located beneath the gate structure 16 may be referred to herein as a semiconductor fin body 15b. The anneal process used in forming the source region 26A and the drain region 26D may be a rapid thermal anneal, furnace annealing, flash annealing, laser annealing or any suitable combination of those techniques. The annealing temperature may range from 600° to 1300° C. with an anneal time ranging from a millisecond to 30 minutes. In one embodiment, the annealing is done by a flash anneal process at about 1200° C. for twenty (20) milliseconds.

In the embodiment illustrated, both the source-side metal semiconductor alloy 34S and the drain-side metal semiconductor alloy 34D have a topmost surface that is planar, i.e., flat.

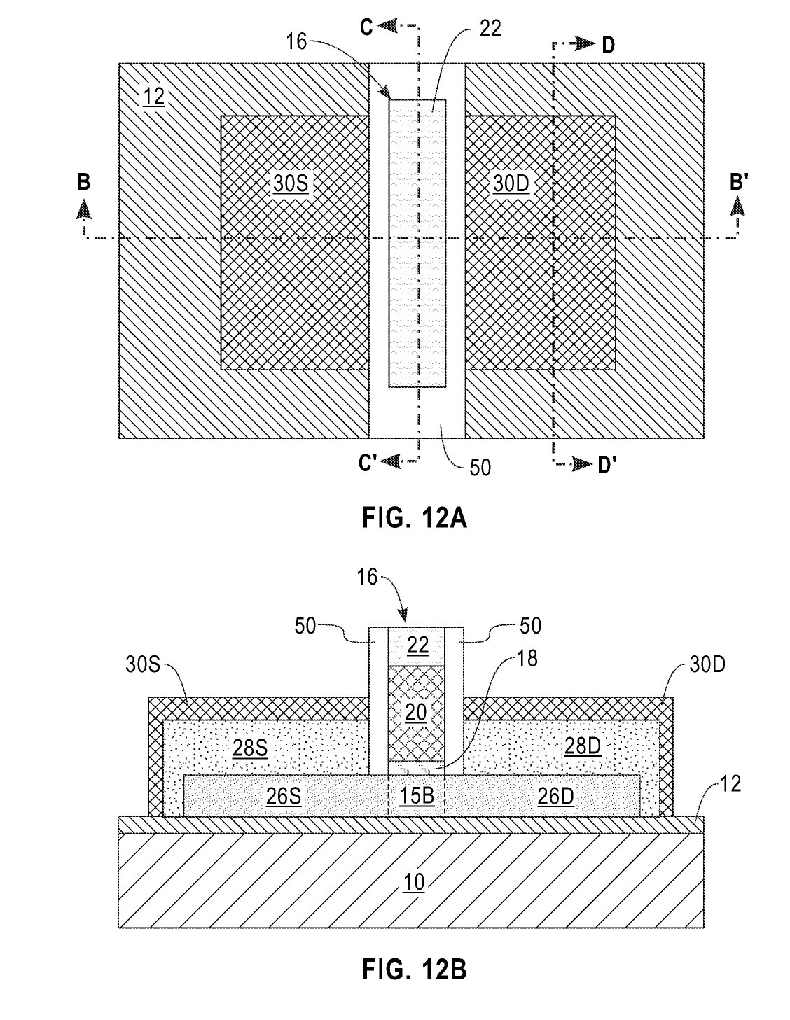

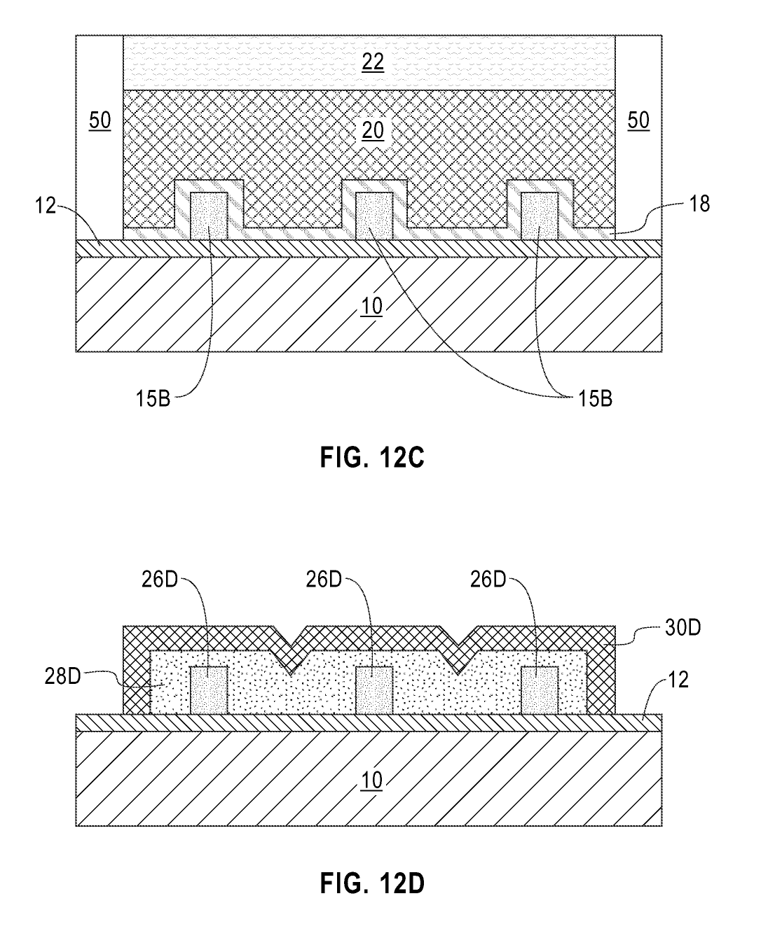

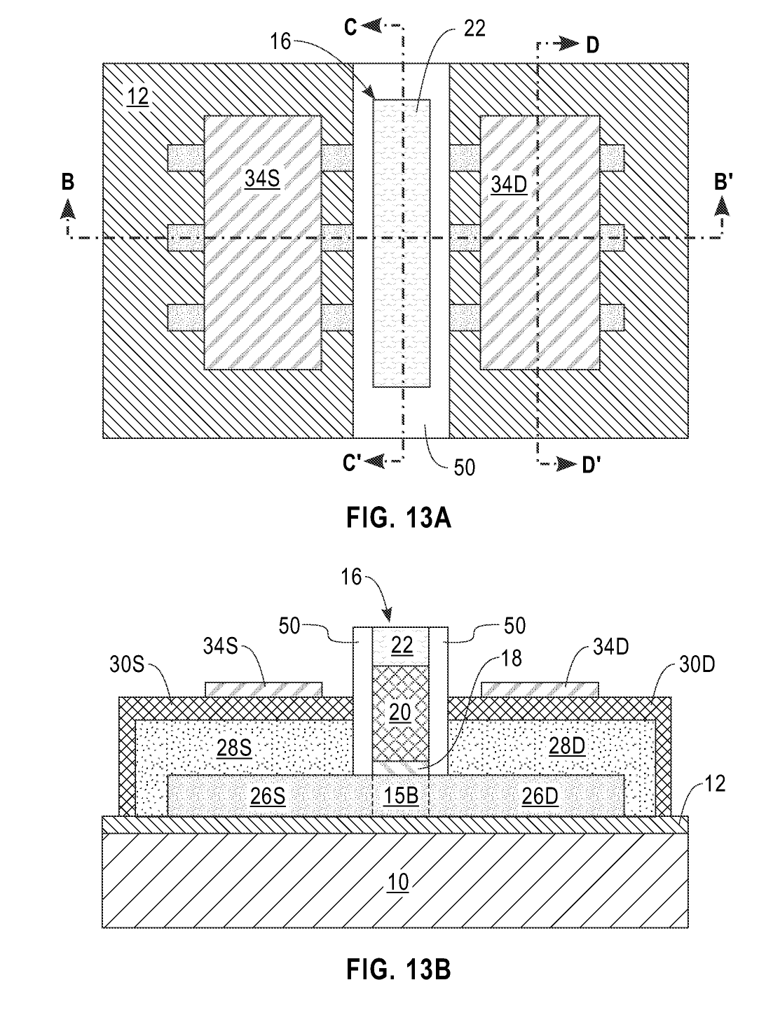

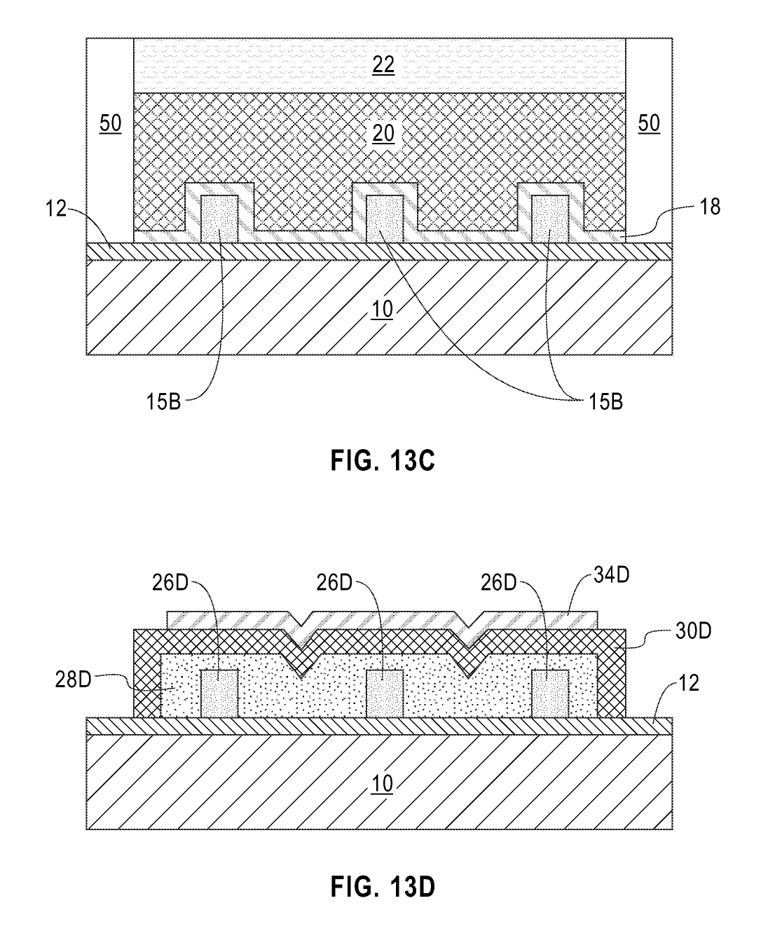

Referring now to FIGS. 12A, 12B, 13C and 12D, there are shown various views of the structure shown in FIGS. 8A, 8B, 8C and 8D after forming a faceted raised source region and a faceted raised drain region and annealing in accordance with an embodiment of the present application. The term “faceted” is used throughout the present application to denote a material layer whose topmost surface has an indentation present therein. In some embodiments, block mask technology can be used to form a first set of raised source and/or raised drain regions that have faceted surfaces, while a second set of raised source and/or drain regions that have planar surfaces.

The faceted raised source region comprises, from bottom to top, a faceted source-side phosphorus doped epitaxial semiconductor material portion 28S and a faceted source-side arsenic doped epitaxial semiconductor material portion 30S, and a faceted raised drain region comprising from bottom to top, the faceted drain-side phosphorus doped epitaxial semiconductor material portion 28D and a drain-side arsenic doped epitaxial semiconductor material portion 30D.

The faceted surfaces can be achieved by employing a timed epitaxial merge. During the merger, <100> bound diamond shape epitaxy is grown around each semiconductor fin. Faceted surfaces provide a means to improve the contact area of the structure.

Referring now to FIGS. 13A, 13B, 13C and 13D, there are shown various views of the structure shown in FIGS. 12A, 12B, 12C and 12D after forming a faceted source-side metal semiconductor alloy 36S atop the faceted raised source region and a faceted drain-side metal semiconductor alloy 36D atop the faceted raised drain region.

In any of the finFET embodiments mentioned above, there is provided a semiconductor structure that includes a gate structure 16 located on a first portion (i.e., body part 15B) of a semiconductor material (i.e., semiconductor fin 15). The structure also includes a raised source region located on a second portion of the semiconductor material (i.e., semiconductor fin) and on one side of the gate structure 16, wherein the raised source region comprises, from bottom to top, a source-side phosphorus doped epitaxial semiconductor material portion 28S and a source-side arsenic doped epitaxial semiconductor material portion 30D. The structure further includes a raised drain region located on a third portion of the semiconductor material (i.e., semiconductor fin) and on another side of the gate structure 16, wherein the raised drain region comprises from, bottom to top, a drain-side phosphorus doped epitaxial semiconductor material portion 28D and a drain-side arsenic doped epitaxial semiconductor material portion 30D.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising:
a gate structure located on a first portion of a semiconductor material;
a raised source region located on a second portion of said semiconductor material and on one side of said gate structure, wherein said raised source region comprises, from bottom to top, a source-side phosphorus doped epitaxial semiconductor material portion and a source-side arsenic doped epitaxial semiconductor material portion; and
a raised drain region located on a third portion of said semiconductor material and on another side of said gate structure, wherein said raised drain region comprises from bottom to top, a drain-side phosphorus doped epitaxial semiconductor material portion and a drain-side arsenic doped epitaxial semiconductor material portion.

2. The semiconductor structure of claim 1, wherein a first dielectric spacer is positioned between said gate structure and both said raised source region and said raised drain region and located on a vertical sidewall of said gate structure.

3. The semiconductor structure of claim 1, further comprising a source-side metal semiconductor alloy portion located on a surface of said source-side arsenic doped epitaxial semiconductor material portion and a drain-side metal semiconductor alloy portion located on a surface of said drain-side arsenic doped epitaxial semiconductor material portion.

4. The semiconductor structure of claim 2, further comprising a second dielectric spacer on each side of said gate structure, wherein said second dielectric spacer on one side of said gate structure contains a sidewall surface contacting a sidewall of said first spacer and a base surface contacting a lateral sidewall of said source-side arsenic doped epitaxial semiconductor material portion, and said second dielectric spacer on said other side of said gate structure contains a sidewall surface contacting a sidewall of said first spacer and a base surface contacting a lateral sidewall of said drain-side arsenic doped epitaxial semiconductor material portion.

5. The semiconductor structure of claim 1, wherein said semiconductor, said source-side phosphorus doped epitaxial semiconductor material portion, said source-side arsenic doped epitaxial semiconductor material portion, said drain-side phosphorus doped epitaxial semiconductor material portion and said drain-side arsenic doped epitaxial semiconductor material portion have a same crystal orientation.

6. The semiconductor structure of claim 1, wherein said semiconductor material is a semiconductor fin, and wherein said gate structure lies perpendicular and straddles said semiconductor fin at said first portion.

7. The semiconductor structure of claim 6, wherein each of said source-side phosphorus doped epitaxial semiconductor material portion and said drain-side phosphorus doped epitaxial semiconductor material portion has a planar topmost surface located above a topmost surface of said semiconductor fin.

8. The semiconductor structure of claim 7, wherein each of said source-side arsenic doped epitaxial semiconductor material portion and said drain-side arsenic doped epitaxial semiconductor material portion has a planar bottom surface and a planar topmost surface.

9. The semiconductor structure of claim 8, wherein a source-side metal semiconductor alloy is located on said planar topmost surface of said source-side arsenic doped epitaxial semiconductor material portion and a drain-side metal semiconductor alloy is located on said planar topmost surface of said drain-side arsenic doped epitaxial semiconductor material portion.

10. The semiconductor structure of claim 6, wherein each of said source-side phosphorus doped epitaxial semiconductor material portion and said drain-side phosphorus doped epitaxial semiconductor material portion has a faceted topmost surface.

11. The semiconductor structure of claim 10, wherein each of said source-side arsenic doped epitaxial semiconductor material portion and drain-side arsenic doped epitaxial semiconductor material portion has a faceted topmost surface.

12. The semiconductor structure of claim 8, wherein a source-side metal semiconductor alloy is located on said faceted topmost surface of said source-side arsenic doped epitaxial semiconductor material portion and a drain-side metal semiconductor alloy is located on said faceted topmost surface of said drain-side arsenic doped epitaxial semiconductor material portion.

13. The semiconductor structure of claim 1, wherein said semiconductor material comprises a plurality of parallel orientated and spaced apart semiconductor fins, and wherein said gate structure lies perpendicular and straddles each semiconductor fin at said first portion, and wherein said raised source region and said raised drain region merge neighboring semiconductor fins of said plurality of semiconductor fins.

14. A method of forming a semiconductor structure comprising:
forming a gate structure on a first portion of a semiconductor material;
forming a source-side phosphorus doped epitaxial semiconductor material portion on one side of said gate structure, and a drain-side phosphorus doped epitaxial semiconductor material portion on another side of said gate structure;
forming a source-side arsenic doped epitaxial semiconductor material portion on an uppermost surface of said source-side phosphorus doped epitaxial semiconductor material portion, and a drain-side arsenic doped epitaxial semiconductor material portion on an uppermost surface of said drain-side phosphorus doped epitaxial semiconductor material portion; and
diffusing dopant from said source-side phosphorus doped epitaxial semiconductor material portion downwards into a second portion of said semiconductor material and formation of a source region, and dopant from said drain-side phosphorus doped epitaxial semiconductor material portion downwards into a third portion of said semiconductor material and formation of a drain region.

15. The method of claim 14, wherein said semiconductor material comprises a least one semiconductor fin, and said at least one semiconductor fin is formed by:
providing a semiconductor-on-insulator substrate comprising, from bottom to top, a handle substrate, an insulator and a topmost semiconductor layer;
patterning said topmost semiconductor layer by lithography and etching.

16. The method of claim 14, wherein said forming said source-side phosphorus doped epitaxial semiconductor material portion and said drain-side phosphorus doped epitaxial semiconductor material portion comprise an in-situ doped epitaxial growth process.

17. The method of claim 14, wherein said forming said source-side arsenic doped epitaxial semiconductor material portion and said drain-side arsenic doped epitaxial semiconductor material portion comprise an in-situ doped epitaxial growth process.

18. The method of claim 14, wherein said source-side phosphorus doped epitaxial semiconductor material portion, said drain-side phosphorus doped epitaxial semiconductor material portion, said source-side arsenic doped epitaxial semiconductor material portion and said drain-side arsenic doped epitaxial semiconductor material portion each have a faceted upper surface.

19. The method of claim 14, further comprising forming a source-side metal semiconductor alloy on a topmost surface of source-side arsenic doped epitaxial semiconductor material portion, and a drain-side metal semiconductor alloy on a topmost surface of drain-side arsenic doped epitaxial semiconductor material portion.

20. The method of claim 19, wherein a first dielectric spacer is present on each side of said gate structure and on vertical sidewalls of said gate structure and wherein prior to forming said source-side metal semiconductor alloy and said drain-side metal semiconductor alloy, a second dielectric spacer is formed on each side of said gate structure, wherein said second dielectric spacer present on one side of said gate structure is in contact with said first dielectric spacer and in contact with a surface said source-side arsenic doped epitaxial semiconductor material portion, and wherein said second dielectric spacer present on another side of said gate structure is in contact with said first dielectric spacer and in contact with a surface said drain-side arsenic doped epitaxial semiconductor material portion.
